(19) United States
(12) Patent Application Publication
(10) Pub. No.: US 2026/0107567 A1
(43) Pub. Date: Apr. 16, 2026

(54) SEMICONDUCTOR DEVICE

(71) Applicant: Samsung Electronics Co., Ltd., Suwon-si (KR)

(72) Inventors: Hyunsoo KIM, Suwon-si (KR); Jaeho JEON, Suwon-si (KR); Donghoon HWANG, Suwon-si (KR); Minwoo KIM, Suwon-si (KR); Byungho MOON, Suwon-si (KR)

(21) Appl. No.: 19/342,924

(22) Filed: Sep. 29, 2025

(30) Foreign Application Priority Data
Oct. 15, 2024 (KR) 10-2024-0140464

(51) Int. Cl. H10D 84/83; H10D 30/00; H10D 30/01; H10D 30/47; H10D 62/10; H10D 62/80; H10D 64/01; H10D 84/01

(52) U.S. Cl. CPC H10D 84/832; H10D 30/481; H10D 30/502; H10D 62/121; H10D 62/883; H10D 30/017; H10D 30/0191; H10D 64/021; H10D 84/0128; H10D 84/0147

(57) ABSTRACT

Provided is a semiconductor device by which the integration level is improved, and specifically provided is a semiconductor device including a gate electrode extending lengthwise in a first direction, a plurality of channel layers that penetrate the gate electrode in a second direction intersecting the first direction, and are spaced apart in the first direction, and a gate insulating film including a plurality of gate insulating film patterns, each gate insulating film pattern at least partially covering a respective channel layer of the plurality of channel layers, wherein a height of each respective channel layer of the plurality of channel layers in a third direction intersecting with the first direction and the second direction is greater than a width of the respective channel layer of the plurality of channel layers in the first direction.

### CROSS-REFERENCE TO RELATED APPLICATIONS

This application claims the benefit of Korean Patent Application No. 10-2024-0140464, filed on Oct. 15, 2024, in the Korean Intellectual Property Office, the disclosure of which is incorporated herein by reference in its entirety.

### BACKGROUND

### 1. Field of the Invention

Example embodiments relate to a semiconductor device.

### 2. Description of the Related Art

A transistor is a semiconductor device that performs an electrical switching function and is used in various electronic products such as memory and driver ICs. Research is being conducted to use two-dimensional (2D) materials to reduce the size of semiconductor devices. Such 2D materials have stable and excellent properties even at a thickness of less than 1 nm and thus the 2D materials are attracting interest as materials that can overcome the limitations of performance degradation due to shrinking size of semiconductor devices.

As semiconductor devices become more highly integrated, gate electrodes, sources, and drains of the semiconductor devices are connected to the metal wiring of a back end of line (BEOL) through contact structures. A method to place at least some of the BEOL wiring on the backside of the semiconductor device is emerging as a way to achieve high integration of semiconductor devices.

### SUMMARY

An aspect provides a semiconductor device by which the integration level is improved. The technical tasks to be achieved by the present example embodiments are not limited to the technical tasks described above, and other technical tasks may be inferred from the following example embodiments by those skilled in the art.

According to an aspect, there is provided a semiconductor device including a gate electrode extending lengthwise in a first direction, a plurality of channel layers that penetrate the gate electrode in a second direction intersecting the first direction, and are spaced apart in the first direction, and a gate insulating film including a plurality of gate insulating film patterns, each gate insulating film pattern at least partially covering each respective channel layer of the plurality of channel layers, wherein a height of each respective channel layer of the plurality of channel layers in a third direction intersecting the first direction and the second direction is greater than a width of the respective channel layer in the first direction.

According to an aspect, there is provided a semiconductor device including a gate electrode extending lengthwise in a first direction, a plurality of channel layers that penetrate the gate electrode in a second direction intersecting the first direction, are spaced apart in the first direction, and include a 2D material between 0.1 nanometers and 10 nanometers thick, a gate insulating film including a plurality of gate insulating film patterns, each gate insulating film pattern at least partially covering a respective channel layer of the plurality of channel layers, a source/drain pattern that is connected to at least one of the plurality of channel layers in the second direction, a frontside interlayer insulating film that covers an upper surface of the gate electrode and an upper surface of the source/drain pattern in a third direction intersecting the first direction and the second direction, a backside interlayer insulating film that covers a lower surface of the gate electrode and a lower surface of the source/drain pattern in the third direction, a frontside gate contact that penetrates the frontside interlayer insulating film to be connected with the gate electrode, and a backside gate contact that penetrates the backside interlayer insulating film to be connected with the gate electrode, wherein a height of each respective channel layer of the plurality of channel layers in the third direction is greater than a width of the respective channel layer in the first direction.

According to an aspect, there is provided a semiconductor device including a gate electrode extending lengthwise in a first direction, a plurality of channel layers that penetrate the gate electrode in a second direction intersecting the first direction, are spaced apart in the first direction, and include a 2D material between 0.1 nanometers and 10 nanometers thick, a gate insulating film including a plurality of gate insulating film patterns, each gate insulating film pattern at least partially covering a respective channel layer of the plurality of channel layers, and a source/drain pattern that is connected to at least one of the plurality of channel layers in the second direction, wherein the gate insulating film covers upper surfaces and lower surfaces of the plurality of channel layers that are positioned along a third direction intersecting the first direction and the second direction, a height of each respective channel layer of the plurality of channel layers in the third direction is greater than a width of the respective channel layer of the plurality of channel layers in the first direction, the source/drain pattern includes an upper surface that is coplanar with an upper surface of the gate electrode, and the source/drain pattern includes a lower surface that is coplanar with a lower surface of the gate electrode.

Specific details of other example embodiments are included in the detailed description and drawings.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a schematic layout drawing illustrating a semiconductor device according to an example embodiment;

FIG. 2 is a drawing illustrating a cross-section taken along line A-A of FIG. 1;

FIG. 3 is a drawing illustrating a cross-section taken along line B-B of FIG. 1;

FIG. 4 is a drawing illustrating a cross-section along line A-A of FIG. 1 to illustrate a semiconductor device according to an example embodiment;

FIG. 5 is a drawing illustrating a cross-section along line B-B of FIG. 1 to illustrate a semiconductor device according to an example embodiment;

FIG. 6 is a drawing illustrating a cross-section along line A-A of FIG. 1 to illustrate a semiconductor device according to an example embodiment;

FIG. 7 to FIG. 36 are drawings illustrating intermediate operations for explaining a method for manufacturing a semiconductor device illustrated in FIG. 2 and FIG. 3;

FIG. 37 to FIG. 52 are drawings illustrating intermediate operations for explaining a method for manufacturing a semiconductor device illustrated in FIG. 4 and FIG. 5; and

FIG. 53 to FIG. 58 are drawings illustrating intermediate operations for explaining a method for manufacturing a semiconductor device illustrated in FIG. 6.

### DETAILED DESCRIPTION

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. Two items described as “directly connected” to each other or as “contacting” or “in contact with” each other do not have any intervening elements at the point of contact. The terms “have,” “may have,” “include,” and “may include” as used herein indicate the presence of corresponding features (for example, elements such as numerical values, functions, operations, or parts), and do not preclude the presence of additional features. Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

In the present disclosure, terms “first,” “second” and so on may be used to describe various components. However, the components are not limited by the terms, and the terms may be used for the purpose of distinguishing one component from another. Within the scope of the technical idea of the present disclosure, the first component may be named as the second component. Similarly, the second component may also be named the first component. Further, the shape and size of components may be exaggerated to emphasize clear explanation.

Further, in the following description, expressions such as an upper side, top, a lower side, bottom, a side, front and a back side are expressed based on the direction shown in the drawing. If the direction of the object changes, it may be expressed differently. The shapes and sizes of elements in the drawings may be exaggerated for clearer explanation.

It should be understood that the width of a conductor (e.g., a gate or wiring) is in a direction perpendicular to the extending direction of the conductor, where the extending direction is the path of the conductor (e.g., corresponding to the current path provided by the conductor). As the entire path of a conductor may not be linear, it should be appreciated that the extending direction of a conductor may change along the length of the conductor (and likewise, the width direction changes). For a linear segment of conductor, the length of the conductor segment in the extending direction is greater than its width (perpendicular to that extending direction).

As used herein, a semiconductor device may refer, for example, to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices. Semiconductor packages may include a package substrate, one or more semiconductor chips, and an encapsulant formed on the package substrate and covering the semiconductor chips.

Hereinafter, example embodiments according to the technical idea of the present disclosure will be described with reference to the attached drawings.

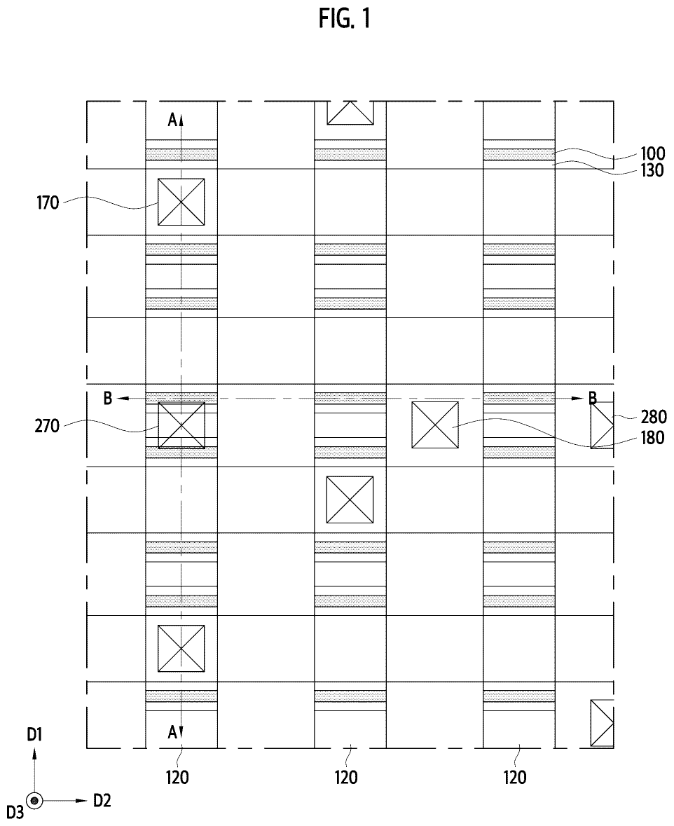

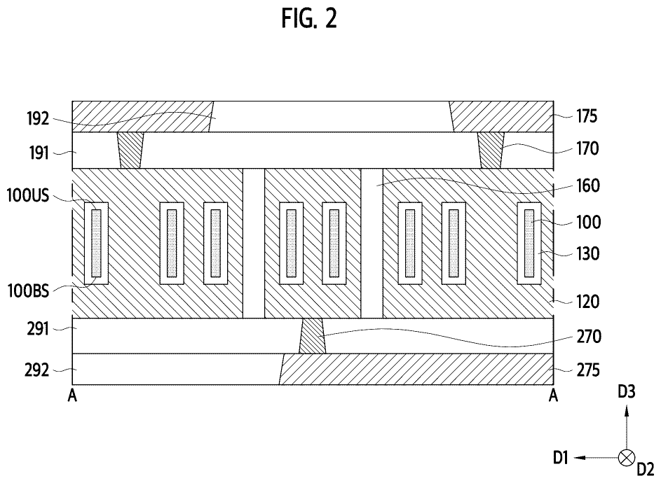

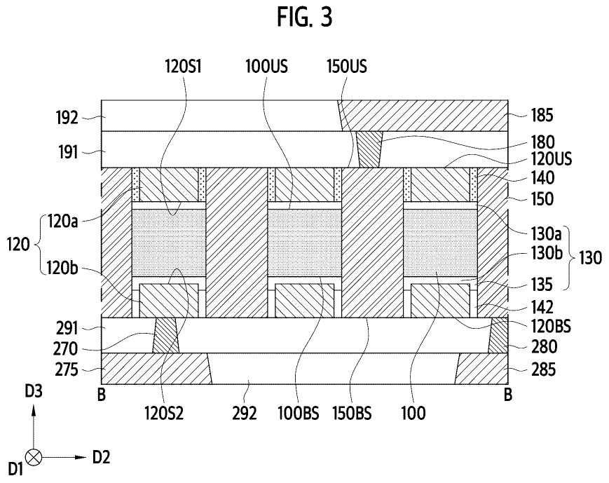

FIG. 1 is a schematic layout drawing illustrating a semiconductor device according to an example embodiment. FIG. 2 is a drawing illustrating a cross-section taken along line A-A of FIG. 1. FIG. 3 is a drawing illustrating a cross-section taken along line B-B of FIG. 1.

Referring to FIG. 1 to FIG. 3, a semiconductor device (e.g., part of an integrated circuit that may be formed as a semiconductor chip) according to the example embodiments may include a plurality of channel layers 100, a gate electrode 120, a gate insulating film 130, a first gate spacer 140, a second gate spacer 142, a source/drain pattern 150, a gate separation pattern 160, a frontside interlayer insulating film (a first frontside interlayer insulating film 191 and a second frontside interlayer insulating film 192), a frontside gate contact 170, a frontside source/drain contact 180, a backside interlayer insulating film (a first backside interlayer insulating film 291 and a second backside interlayer insulating film 292), a backside gate contact 270 and a backside source/drain contact 280.

According to some example embodiments, the plurality of channel layers 100 may be placed in the first direction D1. The first direction D1 may be the direction in which the gate electrode 120 extends. The plurality of channel layers 100 may be spaced apart in the first direction D1 within the gate electrode 120. Even though FIG. 2 illustrates that a distance between two channel layers 100 spaced apart with the gate separation pattern 160 therebetween and a distance between two channel layers 100 with the frontside gate contact 170 placed on top are greater than the distance between two channel layers 100 that are placed adjacently without the gate separation pattern 160, example embodiments are not limited thereto. The distance at which the plurality of channel layers 100 are spaced apart from each other in the first direction D1 may vary depending on the example embodiment. In some embodiments, the plurality of channel layers 100 may be placed (e.g., arranged) in both the first and second directions D1 and D2, as illustrated in FIGS. 2 and 3. Accordingly, a plurality of the channel layers 100 may be placed in the second direction D2. The second direction D2 may be the direction in which the gate electrode 120 and the source/drain pattern 150 are alternately placed. The plurality of channel layers 100 may be placed to be spaced apart in the second direction D2 with the source/drain pattern 150 between them.

According to some example embodiments, the plurality of channel layers 100 do not overlap each other in the third direction D3. The third direction D3 may be a direction intersecting the first direction D1 and the second direction D2. The plurality of channel layers 100 each may be placed one by one in the first and second directions D1 and D2, at the same vertical height in the third direction D3, and each of the plurality of channel layers 100 may not be stacked with other channel layers 100.

According to some example embodiments, each channel layer of the plurality of channel layers 100 may comprise a channel of a transistor and may be surrounded by the gate electrodes 120. The plurality of channel layers 100 may penetrate the gate electrode 120 in the second direction D2. Each of the plurality of channel layers 100 penetrating the gate electrode 120 may be connected to the source/drain pattern 150 in the second direction D2. For example, as shown in FIG. 3, each channel layer (or row thereof along the first direction D1) spaced apart in the second direction D2 may be separated from the adjacent channel layer in the second direction D2 by a source/drain pattern 150. In some embodiments, at least one of the plurality of channel layers 100 may be connected to the source/drain pattern 150 in the second direction D2.

According to some example embodiments, each channel layer of the plurality of channel layers 100 may be surrounded by a gate insulating film pattern of the gate insulating film 130. For example, the entire upper surfaces 100US (e.g., top surfaces 100US) of the plurality of channel layers 100 and the entire bottom surfaces 100BS (e.g., lower surfaces 100BS) of the plurality of channel layers 100 placed along the third direction D3 may be covered by a gate insulating layer such as the gate insulating film 130. The entire upper surfaces 100US of the plurality of channel layers 100 and the entire bottom surfaces 100BS of the plurality of channel layers 100 may overlap the gate insulating film 130 in the third direction D3.

According to some example embodiments, the height of each of the plurality of channel layers 100 in the third direction D3 may be greater than the width of each of the plurality of channel layers 100 along the first direction D1. For example, in a cross section including the first direction D1 and the third direction D3, each of the plurality of channel layers 100 may have a shape extending in the third direction D3, as shown in FIG. 2. Likewise, the length of each of the plurality of channel layers 100 in the second direction D2 may be greater than its width along the first direction D1. In some embodiments, the thickness of each of the plurality of channel layers 100 in the first direction D1 may be less than the thickness of the gate insulating film 130 in the first direction D1.

FIG. 2 and FIG. 3 illustrate that each of the plurality of channel layers 100 is a single film, but example embodiments are not limited thereto. Each of the plurality of channel layers 100 may include a multilayer film.

According to some example embodiments, the plurality of channel layers 100 may include or may consist of 2D materials, such as materials comprising a plurality of atomically thin sheets, which may be weakly bound to each other. For example, the plurality of channel layers 100 may include MoS₂, MoSe₂, MoTe₂, WS₂, WSe₂, MoTe₂ and/or PtSe₂. For example, the plurality of channel layers 100 may include a transition metal dichalcogenide (TMD). For example, the 2D materials may be less than 10 nanometers thick. In other examples, the 2D materials may be between 0.1 and 10 nanometers, between 0.3 and 10 nanometers, between 0.5 and 10 nanometers, between 2 and 10 nanometers, and in some cases, between 3 and 8 nanometers. The thickness of each of the plurality of channel layers 100 including 2D materials may be 0.3 nanometer to 0.5 nanometer. The plurality of channel layers 100 may be a single layer or a multilayer (multiple single layers stacked). In some embodiments, the width of the plurality of channel layers 100 in the first direction D1 may be between 0.3 nanometers and 0.5 nanometers.

According to some example embodiments, the bond energy (e.g., binding energy or bond strength) of a material included in the plurality of channel layers 100 to a material included in the gate insulating film 130 may be greater than its bond energy to a material included in the second gate spacer 142.

According to some example embodiments, the gate electrode 120 may extend lengthwise in the first direction D1. An item, layer, or portion of an item or layer described herein as extending “lengthwise” in a particular direction has a length in the particular direction and a width perpendicular to that direction, where the length is greater than the width. A plurality of gate electrodes 120 may be placed in the second direction D2. The gate electrodes 120 may intersect the plurality of channel layers 100. The gate electrodes 120 may surround each channel layer of the plurality of channel layers 100. In the second direction D2, the gate electrodes 120 may be placed on both sides of the source/drain pattern 150. Accordingly, the gate electrodes 120 surrounding the channel layers 100 can provide superior electrical contact for 2D (e.g., atomically thin) channels.

According to some example embodiments, all gate electrodes 120 placed on both sides of the source/drain pattern 150 may be normal gate electrodes used as gates of the transistor. In another example embodiment, the gate electrodes 120, located on one side of the source/drain pattern 150, are used as the gates of the transistor, but the gate electrodes 120 placed on the other side of the source/drain pattern 150 may be dummy gate electrodes. As used herein, the term “dummy” is used to refer to a component that has the same or similar structure and shape as other components but does not have a substantial function (e.g., to convey information). The “dummy” element may only exist as a pattern in the device. In some instances, a “dummy” element may be electrically floated, or may be connected to various voltage sources but otherwise not provide the same functionality of the non-dummy element it represents.

According to some example embodiments, the gate electrode 120 may include at least one of a metal, a metal alloy, a conductive metal nitride, a metal silicide, a doped semiconductor material, a conductive metal oxide, or a conductive metal oxynitride. For example, the gate electrode 120 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or any combination thereof. However, the gate electrode 120 is not limited thereto. The conductive metal oxide and conductive metal oxynitride may include oxidized forms of the above-described substances, but are not limited thereto.

According to some example embodiments, the gate electrode 120 may include a first part (e.g., a first gate electrode part) 120a and a second part e.g., a second gate electrode part) 120b. The first part 120a may be placed on each of the upper surfaces 100US of the plurality of channel layers 100 in the third direction D3. The first part 120a may face each of the upper surfaces 100US of the plurality of channel layers 100 in the third direction D3. The first part 120a may have a first facing surface 120S1 facing each of the upper surfaces 100US of the plurality of channel layers 100. The second part 120b may be placed at the lower portion of (e.g., beneath and in contact with) each of the bottom surfaces 100BS of the plurality of channel layers 100 in the third direction D3. The second part 120b may face each of the bottom surfaces 100BS of the plurality of channel layers 100 in the third direction D3. The second part 120b may have a second facing surface 120S2 that faces each of the bottom surfaces 100BS of the plurality of channel layers 100.

According to some example embodiments, the first part 120a does not overlap the gate insulating film 130 in the second direction D2. For example, the entire side of the first part 120a, which is placed in the second direction D2, may be covered by the first gate spacer 140. At least a portion of the second part 120b may overlap the gate insulating film 130 in the second direction D2. For example, a portion of the side of the second part 120b, which is placed in the second direction D2, may be covered by the gate insulating film 130, and the remaining portion may be covered by the second gate spacer 142. In some embodiments, the side of the second part 120b which is placed in the second direction D2 may be covered by the second gate spacer 142.

According to some example embodiments, upper surfaces 120US of the gate electrode 120 and bottom surfaces 120BS of the gate electrode 120 may be opposite surfaces in the third direction D3. The upper surfaces 120US of the gate electrode 120 may be the upper surfaces of the first part 120a. The bottom surface 120BS of the gate electrode 120 may be the bottom surface of the second part 120b. The upper surface 120US of the gate electrode 120 may be covered by the first frontside interlayer insulating film 191. The bottom surface 120BS of the gate electrode 120 may be covered by the first backside interlayer insulating film 291. FIG. 2 and FIG. 3 illustrate that each of the upper surfaces 120US of the gate electrode 120 and the bottom surfaces 120BS of the gate electrode 120 is in contact with the first frontside interlayer insulating film 191 and the first backside interlayer insulating film 291. However, example embodiments are not limited thereto. For example, a gate capping film may be placed between the upper surfaces 120US of the gate electrode 120 and the first frontside interlayer insulating film 191, and a gate capping film may be placed between the bottom surfaces 120BS of the gate electrode 120 and the first backside interlayer insulating film 291. In some embodiments, the source/drain pattern 150 may include an upper surface that is coplanar with the upper surface 120US of the gate electrode 120, and the source/drain pattern 150 may include a lower surface that is coplanar with the bottom surface 120BS of the gate electrode 120.

According to some example embodiments, the gate insulating film 130 may be positioned between the plurality of channel layers 100 and the gate electrode 120. The gate insulating film 130 may surround (e.g., coat or cover) each channel layer of the plurality of channel layers 100. In some examples, the gate insulating film 130 may coat or cover most sides of each channel layer of the plurality of channel layers 100, without completely surrounding all surfaces thereof. For example, the gate insulating film 130 may cover the upper surfaces 100US of the plurality of channel layers 100 and the bottom surfaces 100BS of the plurality of channel layers 100, as shown in FIG. 2. Likewise, the gate insulating film 130 may cover edges or side surfaces of channel layers 100 (e.g., edges or side surfaces perpendicular to the first direction D1), as shown in FIG. 2. However, in some examples, the gate insulating film 130 does not cover edges or side surfaces perpendicular to the second direction D2, as shown in FIG. 3.

According to some example embodiments, the gate insulating film 130 may include an upper surface part 130a, a bottom surface part 130b (e.g., lower surface part 130b) and a protruding part 135. The upper surface part 130a may be disposed on each of the upper surfaces 100US of the plurality of channel layers 100. The upper surface part 130a may cover each of the upper surfaces 100US of the plurality of channel layers 100. The bottom surface part 130b may be placed at the lower portion of (e.g., beneath and in contact with) each of the bottom surfaces 100BS of the plurality of channel layers 100. The bottom surface part 130b may cover each of the bottom surfaces 100BS of the plurality of channel layers 100. The protruding part 135 may protrude further downwards from the bottom surface part 130b toward the bottom surfaces 120BS of the gate electrode 120 than the second facing surface 120S2 of the second part 120b of the gate electrode 120. The protruding part 135 may overlap the second part 120b of the gate electrode 120 in the second direction D2. The protruding part 135 may overlap the second gate spacer 142 in the third direction D3. The gate insulating film 130 may include a plurality of gate insulating film patterns, each gate insulating film pattern contacting and surrounding a respective channel layer (e.g., each channel layer) of the plurality of channel layers 100. In some embodiments, each gate insulating film pattern may cover a respective upper surface and a respective lower surface of one respective channel layer, and covers side surfaces of the one respective channel layer extending between the respective upper surface and the respective lower surface.

According to some example embodiments, the thickness of the gate insulating film 130 along the third direction D3 on the upper surfaces 100US of the plurality of channel layers 100 may be constant. The upper surface part 130a of the gate insulating film 130 disposed on each of the upper surfaces 100US of the plurality of channel layers 100 may have a constant thickness in the third direction D3. The thickness of the gate insulating film 130 along the third direction D3 at the lower portion of the bottom surfaces 100BS of the plurality of channel layers 100 may not be constant. The bottom surface part 130b and the protruding part 135 of the gate insulating film 130 are placed at a lower portion of (e.g., beneath and in contact with) each of the bottom surfaces 100BS of the plurality of channel layers 100, and thus the thickness of the gate insulating film 130 along the third direction D3 in the area where the protruding part 135 is placed may be greater than the thickness of the gate insulating film 130 along the third direction D3 in the area where the protruding part 135 is not placed.

According to some example embodiments, the gate insulating film 130 may include silicon oxide, silicon-germanium oxide, germanium oxide, silicon oxynitride, silicon nitride, or a high-k material having a dielectric constant greater than silicon oxide. For example, the high-k material may include at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

FIG. 2 and FIG. 3 illustrate that the gate insulating film 130 is a single layer, but the illustration is only for convenience of explanation, and the present disclosure is not limited thereto. The gate insulating film 130 may include a plurality of films. The gate insulating film 130 may include an interfacial layer disposed between the plurality of channel layers 100 and the gate electrode 120, and a high-k insulating film. The interfacial layer may include silicon oxide, and the high-k insulating film may include at least one of the high-k materials described above.

A semiconductor device according to some example embodiments may include a negative capacitance (NC) FET using a negative capacitor. For example, the gate insulating film 130 may include a ferroelectric material film having ferroelectric properties and a paraelectric material film having paraelectric properties.

According to some example embodiments, the ferroelectric material film may have negative capacitance, and the paraelectric material film may have positive capacitance. For example, when two or more capacitors are connected in series and the capacitance of each capacitor has a positive value, the overall capacitance is reduced compared to the capacitance of each individual capacitor. On the other hand, when at least one of the capacitances of two or more capacitors connected in series has a negative value, the total capacitance may be positive and greater than the absolute value of each individual capacitance.

According to some example embodiments, when a ferroelectric material film with negative capacitance and a paraelectric material film with positive capacitance are connected in series, the overall capacitance value of the ferroelectric material film and paraelectric material film connected in series may increase. By using the increase in overall capacitance value, transistors containing the ferroelectric material film may have a subthreshold swing (SS) of less than 60 mV/decade at room temperature.

According to some example embodiments, the ferroelectric material film may have ferroelectric properties. For example, the ferroelectric material film may include at least one of hafnium oxide, hafnium zirconium oxide, barium strontium titanium oxide, barium titanium oxide or lead zirconium titanium oxide. Here, in an example embodiment, the hafnium zirconium oxide may be a material in which hafnium oxide is doped with zirconium (Zr). In another example embodiment, the hafnium zirconium oxide may be a compound of hafnium (Hf), zirconium (Zr), and oxygen (O).

According to some example embodiments, the ferroelectric material film may further contain dopants. For example, the dopants may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). Depending on which ferroelectric material the ferroelectric material film contains, the type of dopant contained in the ferroelectric material film may vary.

When the ferroelectric material film contains hafnium oxide, the dopants included in the ferroelectric material film may include, for example, at least one of gadolinium (Gd), silicon (Si), zirconium (Zr), aluminum (Al), or yttrium (Y).

According to some example embodiments, when the dopant is aluminum (Al), the ferroelectric material film may contain (e.g., be doped with) 3 to 8 atomic % aluminum. Here, the ratio of dopant may be the ratio of aluminum to the sum of hafnium and aluminum.

According to some example embodiments, when the dopant is silicon (Si), the ferroelectric material film may contain 2 to 10 at % silicon. When the dopant is yttrium (Y), the ferroelectric material film may contain 2 to 10 at % yttrium. When the dopant is gadolinium (Gd), the ferroelectric material film may contain 1 to 7 at % gadolinium. When the dopant is zirconium (Zr), the ferroelectric material film may contain 50 to 80 at % zirconium.

According to some example embodiments, the paraelectric material film may have paraelectric properties. For example, the paraelectric material film may include at least one of silicon oxide and a metal oxide having a high dielectric constant. For example, the metal oxide contained in the paraelectric material film may include at least one of hafnium oxide, zirconium oxide or aluminum oxide, but the present disclosure is not limited thereto.

According to some example embodiments, the ferroelectric material film and the paraelectric material film may contain material having the same chemical formula (e.g., polymorphs with different crystal structures). The ferroelectric material film may have ferroelectric properties, but the paraelectric material film may not have ferroelectric properties. For example, when the ferroelectric material film and paraelectric material film contain hafnium oxide, the crystal structure of hafnium oxide included in the ferroelectric material film may be different from the crystal structure of hafnium oxide included in the paraelectric material film.

According to some example embodiments, the ferroelectric material film may have a thickness that exhibits ferroelectric properties. The thickness of the ferroelectric material film may be, for example, 0.5 to 10 nm. However, the ferroelectric material film is not limited thereto. Since the critical thickness that gives rise to the ferroelectric properties may vary for each ferroelectric material, the thickness of the ferroelectric material film may vary depending on the ferroelectric material.

In an example embodiment, the gate insulating film 130 may include a ferroelectric material film. In another example embodiment, the gate insulating film 130 may include a plurality of ferroelectric material films spaced apart from each other. The gate insulating film 130 may have a laminated film structure in which the plurality of ferroelectric material films and a plurality of paraelectric material films are alternately laminated.

According to some example embodiments, the first gate spacer 140 may be placed on both sides of the first part 120a of the gate electrode 120 along the second direction D2. The first gate spacer 140 may be placed on the upper surfaces 100US of the plurality of channel layers 100. The first gate spacer 140 may be placed on the upper surface part 130a of the gate insulating film 130.

According to some example embodiments, the second gate spacer 142 may be placed on both sides of the second part 120b of the gate electrode 120 along the second direction D2. The second gate spacer 142 may be placed beneath each of the bottom surfaces 100BS of the plurality of channel layers 100. The second gate spacer 142 may be placed at a lower portion of the bottom surface part 130b of the gate insulating film 130 and a lower portion of the protruding part 135.

According to some example embodiments, the first gate spacer 140 and the second gate spacer 142 may include at least one of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), or any combination thereof. The first gate spacer 140 and the second gate spacer 142 are illustrated as single films, but this is only for convenience of explanation, and the present disclosure is not limited thereto.

According to some example embodiments, each of the first gate spacer 140 and the second gate spacer 142 may include different substances. For example, the first gate spacer 140 may include silicon oxycarbonitride (SiOCN), and the second gate spacer 142 may include silicon oxide (SiO2).

According to some example embodiments, the source/drain pattern 150 may be connected to the plurality of channel layers 100 in the second direction D2. The plurality of source/drain patterns 150 may be spaced apart in the second direction D2 with the plurality of channel layers 100 therebetween, as shown in FIG. 3. The source/drain pattern 150 may be the source/drain of a transistor or a plurality thereof that use the plurality of channel layers 100 as channel regions. The source/drain pattern 150 may be extended to the third direction D3. The source/drain pattern 150 may be placed between adjacent gate electrodes 120 in the second direction D2.

According to some example embodiments, an upper surface 150US (e.g., top surface 150US) of the source/drain pattern 150 and the upper surfaces 120US (e.g., top surfaces 120US) of the gate electrode 120 may be placed in the same plane. Bottom surfaces 150BS (e.g., lower surfaces 150BS) of the source/drain patterns 150 and the bottom surfaces 120BS (e.g., lower surfaces 120BS) of the gate electrodes 120 may be placed on the same plane.

According to some example embodiments, the source/drain pattern 150 may include at least one of tantalum (Ta), tantalum nitride (TaN), titanium (Ti), titanium nitride (TIN), titanium silicon nitride (TiSiN), ruthenium (Ru), cobalt (Co), nickel (Ni), nickel Boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), aluminum (Al), silver (Ag), gold (Au), manganese (Mn), molybdenum (Mo), or 2D materials. In a semiconductor device according to some example embodiments, the 2D materials may be a metallic material and/or a semiconductor material. The 2D materials may include a plurality of 2D (e.g., atomically thin) polymorph layers, such as a 2D allotrope or a 2D compound. For example, the 2D materials may include at least one of graphene, molybdenum disulfide (MoS2), molybdenum diselenide (MoSe2), tungsten diselenide (WSe2), tungsten disulfide (WS2), but the 2D materials are not limited thereto. Since the 2D materials are only listed as examples, 2D materials that are suitable to be included in the semiconductor device are not limited to what is described above.

According to some example embodiments, the gate separation pattern 160 may cut the gate electrode 120 extending in the first direction D1. The gate separation pattern 160 may penetrate the gate electrode 120 in the third direction D3. For example, the gate separation pattern 160 may separate gate electrodes 120 in the first direction D1. The gate separation pattern 160 may be placed between the plurality of channel layers 100 adjacent in the first direction D1. Even though FIG. 2 illustrates that two channel layers 100 are placed between adjacent gate separation patterns 160 in the first direction D1, and three channel layers 100 are placed on the side of the gate separation pattern 160, example embodiments are not limited thereto. The number of channel layers 100 placed between the gate separation patterns 160 in the first direction D1 may vary depending on the example embodiment.

According to some example embodiments, the gate separation pattern 160 may include at least one of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), or any combination thereof. However, example embodiments are not limited thereto.

According to some example embodiments, the frontside interlayer insulating film (e.g., the first frontside interlayer insulating film 191 and the second frontside interlayer insulating film 192) may be disposed on the upper surfaces 120US of the gate electrode 120 and the upper surface 150US of the source/drain pattern 150. The frontside interlayer insulating film (the first frontside interlayer insulating film 191 and the second frontside interlayer insulating film 192) may cover the upper surfaces 120US of the gate electrode 120 and the upper surface 150US of the source/drain pattern 150.

According to some example embodiments, the frontside interlayer insulating film may include the first frontside interlayer insulating film 191 and the second frontside interlayer insulating film 192. The first frontside interlayer insulating film 191 and the second frontside interlayer insulating film 192 may be sequentially disposed on the upper surface 120US of the gate electrode 120 and the upper surface 150US of the source/drain pattern 150. The first frontside interlayer insulating film 191 may be disposed on the upper surface 120US of the gate electrode 120 and the upper surface 150US of the source/drain pattern 150. The second frontside interlayer insulating film 192 may be disposed on the first frontside interlayer insulating film 191.

According to some example embodiments, the backside interlayer insulating film (the first backside interlayer insulating film 291 and the second backside interlayer insulating film 292) may be disposed at a lower portion of the bottom surfaces 120BS of the gate electrodes 120 and a lower portion of the bottom surfaces 150BS of the source/drain patterns 150. The backside interlayer insulating film (the first backside interlayer insulating film 291 and the second backside interlayer insulating film 292) may cover the bottom surfaces 120BS of the gate electrodes 120 and the bottom surfaces 150BS of the source/drain patterns 150.

According to some example embodiments, the backside interlayer insulating film may include the first backside interlayer insulating film 291 and the second backside interlayer insulating film 292. The first backside interlayer insulating film 291 and the second backside interlayer insulating film 292 may be sequentially placed at lower portions of the bottom surfaces 120BS of the gate electrodes 120 and the bottom surfaces 150BS of the source/drain patterns 150. The first backside interlayer insulating film 291 may be disposed at lower portions of the bottom surfaces 120BS of the gate electrodes 120 and the bottom surfaces 150BS of the source/drain patterns 150. The second backside interlayer insulating film 292 may be placed at a lower portion of the first backside interlayer insulating film 291.

According to some example embodiments, the frontside interlayer insulating film (the first frontside interlayer insulating film 191 and the second frontside interlayer insulating film 192) and the backside interlayer insulating film (the first backside interlayer insulating film 291 and the second backside interlayer insulating film 292) may include at least one of silicon oxide, silicon nitride, silicon oxynitride, or a low-k material. For example, the low-k material may include Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or any combination thereof, but the low-k material is not limited thereto.

According to some example embodiments, the frontside gate contact 170 may be positioned within the first frontside interlayer insulating film 191. The frontside gate contact 170 may be placed on the upper surface 120US of the gate electrode 120. The frontside gate contact 170 may penetrate the first frontside interlayer insulating film 191 in the third direction D3 and be connected to the upper surface 120US of the gate electrode 120. The frontside gate contact 170 may electrically connect a first frontside wiring 175 and the gate electrode 120.

According to some example embodiments, the frontside source/drain contact 180 may be positioned within the first frontside interlayer insulating film 191. The frontside source/drain contact 180 may be placed on the upper surface 150US of the source/drain pattern 150. The frontside source/drain contact 180 may penetrate the first frontside interlayer insulating film 191 in the third direction D3 to be connected to the upper surface 150US of the source/drain pattern. The frontside source/drain contact 180 may electrically connect a second frontside wiring 185 and the source/drain pattern 150.

According to some example embodiments, the backside gate contact 270 may be positioned within the first backside interlayer insulating film 291. The backside gate contact 270 may be placed at the lower portion of the bottom surfaces 120BS of the gate electrode 120. The backside gate contact 270 may penetrate the first backside interlayer insulating film 291 in the third direction D3 and be connected to the bottom surfaces 120BS of the gate electrode 120. The backside gate contact 270 may electrically connect a first backside wiring 275 and the gate electrode 120.

According to some example embodiments, the backside source/drain contact 280 may be positioned within the first backside interlayer insulating film 291. The backside source/drain contact 280 may be placed at the lower portion of the bottom surfaces 150BS of the source/drain pattern 150. The backside source/drain contact 280 may penetrate the first backside interlayer insulating film 291 in the third direction D3 to be connected to the bottom surfaces 150BS of the source/drain pattern 150. The backside source/drain contact 280 may electrically connect a second backside wiring 285 and the source/drain pattern 150.

According to some example embodiments, each of the frontside gate contact 170, the frontside source/drain contact 180, the backside gate contact 270 and the backside source/drain contact 280 may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or 2D materials. In semiconductor devices according to some example embodiments, the 2D materials may be a metallic material and/or a semiconductor material. The 2D materials may include a plurality of 2D (e.g., atomically thin) polymorph layers, such as a 2D allotrope or a 2D compound. For example, 2D materials may include at least one of graphene, molybdenum disulfide (MoS2), molybdenum diselenide (MoSe2), tungsten diselenide (WSe2) and tungsten disulfide (WS2). However, the 2D materials are not limited thereto. For example, the above-described 2D materials are described as examples, and thus the 2D materials that may be included in the semiconductor device of the present invention are not limited to the materials described above. For example, the frontside gate contact 170, the frontside source/drain contact 180, the backside gate contact 270 and the backside source/drain contact 280 may include at least one of aluminum (Al), tungsten (W), cobalt (Co), ruthenium (Ru), silver (Ag), gold (Au), manganese (Mn), or molybdenum (Mo).

FIG. 2 and FIG. 3 illustrate that each of the frontside gate contact 170, the frontside source/drain contact 180, the backside gate contact 270 and the backside source/drain contact 280 is a single film, but example embodiments are not limited thereto. For example, it is apparent that each of the frontside gate contact 170, the frontside source/drain contact 180, the backside gate contact 270 and the backside source/drain contact 280 may have a multilayer film structure including a contact barrier film and a contact filling film.

According to some example embodiments, the first frontside wiring 175 and the second frontside wiring 185 may be placed within the second frontside interlayer insulating film 192. The first backside wiring 275 and the second backside wiring 285 may be placed within the second backside interlayer insulating film 292. For example, the first frontside wiring 175, the second frontside wiring 185, the first backside wiring 275 and the second backside wiring 285 may include at least one of metal, conductive metal nitride, conductive metal carbide, conductive metal oxide, conductive metal carbonitride and 2D materials. FIG. 2 and FIG. 3 illustrate that the first frontside wiring 175, the second frontside wiring 185, the first backside wiring 275, and the second backside wiring 285 have a single conductive film structure. However, the present disclosure is not limited thereto. For example, it is apparent that each of the first frontside wiring 175, the second frontside wiring 185, the first backside wiring 275 and the second backside wiring 285 may have a multilayer film structure including a barrier film and a peeling film.

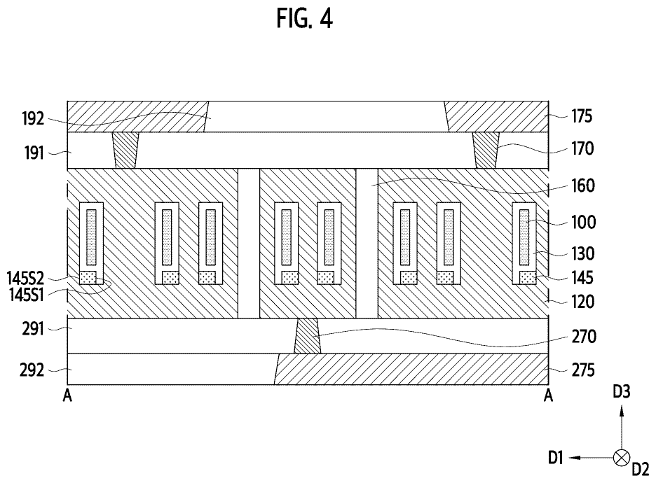

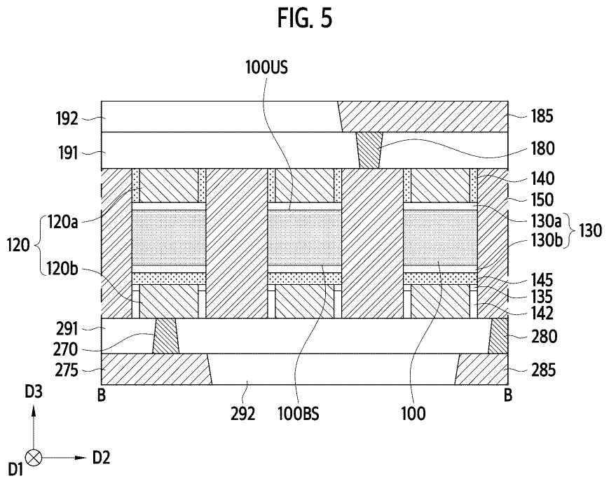

FIG. 4 is a drawing illustrating a cross-section along line A-A of FIG. 1 to illustrate a semiconductor device according to an example embodiment. FIG. 5 is a drawing illustrating a cross-section along line B-B of FIG. 1 to illustrate a semiconductor device according to an example embodiment. The differences from those described with reference to FIG. 1 to FIG. 3 will be mainly explained to explain the semiconductor device according to some other example embodiments.

Referring to FIG. 4 and FIG. 5, in the third direction D3, a dummy spacer 145 may be placed between the plurality of channel layers 100 and the gate electrode 120. The dummy spacer 145 may be placed at the lower portion of each of the bottom surfaces 100BS of the plurality of channel layers 100. The dummy spacer 145 may be placed at the lower portion of the bottom surface part 130b of the gate insulating film 130. The dummy spacer 145 may be placed between the bottom surface part 130b of the gate insulating film 130 and the protruding part 135. The dummy spacer 145 may be surrounded by the gate insulating film 130 and the gate electrode 120. The dummy spacer 145 may be formed depending on the manufacturing conditions of the semiconductor device.

According to some example embodiments, the dummy spacer 145 may include a first surface 145S1 and a second surface 145S2 which are oppositely placed in the first direction D1, as shown in FIG. 4. The gate insulating film 130 may cover the first surface 145S1 of the dummy spacer 145. The gate electrode 120 may cover the second surface 145S2 of the dummy spacer 145.

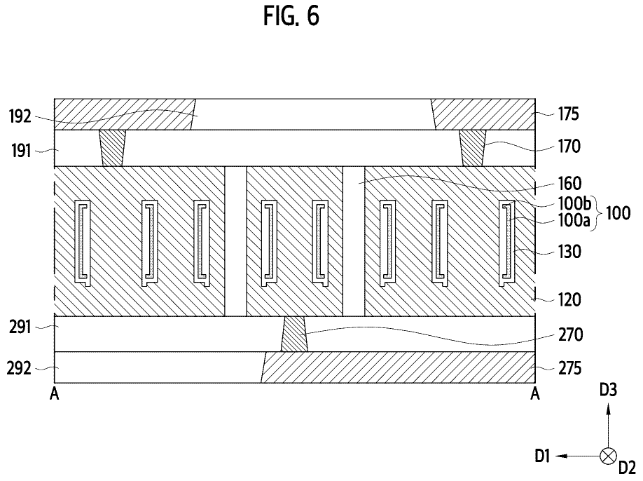

FIG. 6 is a drawing illustrating a cross-section along line A-A of FIG. 1 to illustrate a semiconductor device according to an example embodiment. The differences from those described with reference to FIG. 1 to FIG. 3 will be mainly explained to explain the semiconductor device according to some other example embodiments.

Referring to FIG. 6, each of the plurality of channel layers 100 may include an extended part 100a and a bent part 100b. The extended part 100a may be extended in the third direction D3. The bent part 100b may be bent from the extended part 100a in the first direction D1. The bent part 100b may be bent from the end of the extended part 100a along the third direction D3. The thickness of the gate insulating film 130 placed on the side of the extended part 100a in the direction in which the bent part 100b is bent from the extended part 100a may be greater than the thickness of the gate insulating film 130 placed on the side of the extended part 100a in the direction opposite to the direction in which the bent part 100b is bent from the extended part 100a. The extended part 100a and the bent part 100b may be formed depending on the manufacturing conditions of the semiconductor device.

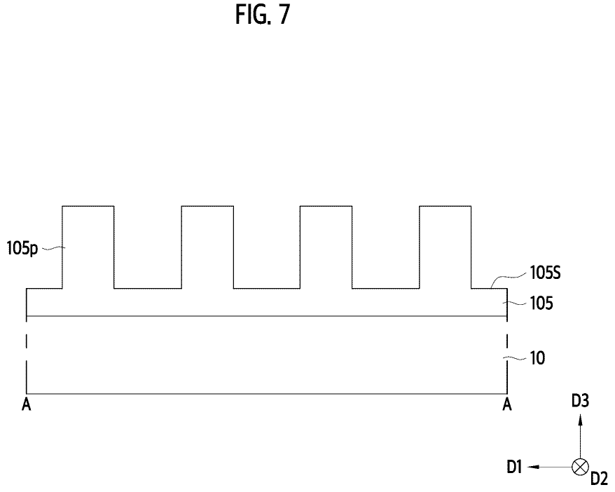

FIG. 7 to FIG. 36 are drawings illustrating intermediate operations for explaining a method for manufacturing a semiconductor device illustrated in FIG. 2 and FIG. 3.

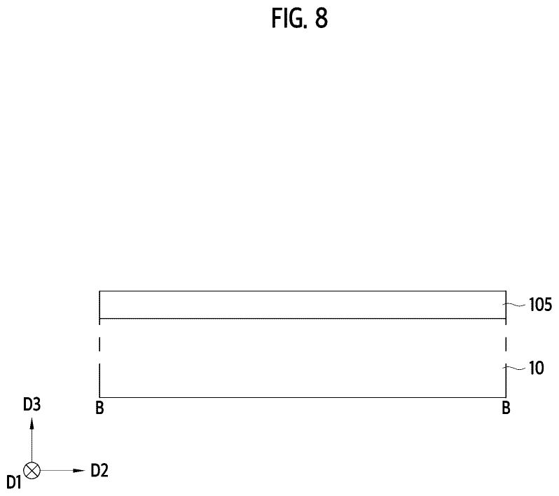

Referring to FIG. 7 and FIG. 8, a first molding structure 105 may be formed on a substrate 10. The first molding structure 105 may be extended in the second direction D2, and may include a plurality of protruding patterns 105p spaced apart from each other in the first direction D1. The plurality of protruding patterns 105p may protrude from a surface 105S of the first molding structure 105 in the third direction D3. The surface 105S of the first molding structure 105 may refer to a surface that is positioned opposite to the surface of the first molding structure 105 that faces the substrate 10.

According to some example embodiments, the substrate 10 may include a semiconductor material. The substrate 10 may be a silicon substrate or silicon-on-insulator (SOI). The substrate 10 may include silicon germanium, silicon germanium on insulator (SGOI), indium antimonide, lead telluride, indium arsenide, indium phosphide, gallium arsenide, or gallium antimonide, but the substrate 10 is not limited thereto. In another example embodiment, the substrate 10 may include at least one of silicon oxide, silicon nitride, silicon oxynitride, or a low-k material.

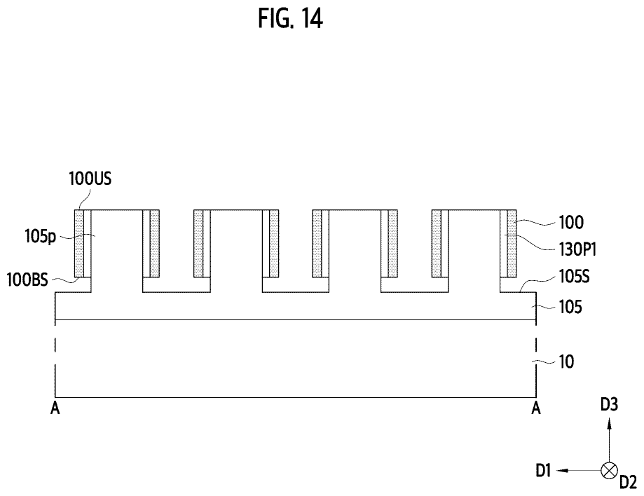

According to some example embodiments, the first molding structure 105 may, for example, include silicon oxide. FIG. 7 illustrates that the width of the plurality of protruding patterns 105p in the first direction D1 is constant, and the plurality of protruding patterns 105p are spaced at regular intervals in the first direction D1, but the present disclosure is not limited thereto. For example, the width of the plurality of protruding patterns 105p in the first direction D1 may be different. The interval between respective protruding patterns of the plurality of protruding patterns 105p in the first direction D1 is not constant and may differ from each other. By adjusting the width and spacing of the plurality of protruding patterns 105p according to the first direction D1, the distance between the plurality of channel layers 100 (in FIG. 14) formed subsequently may be controlled.

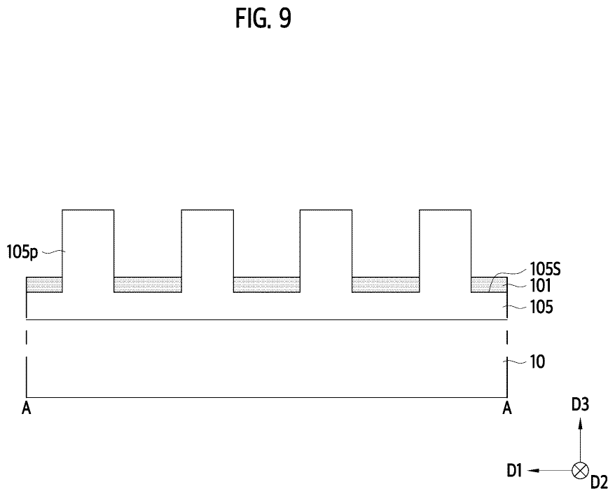

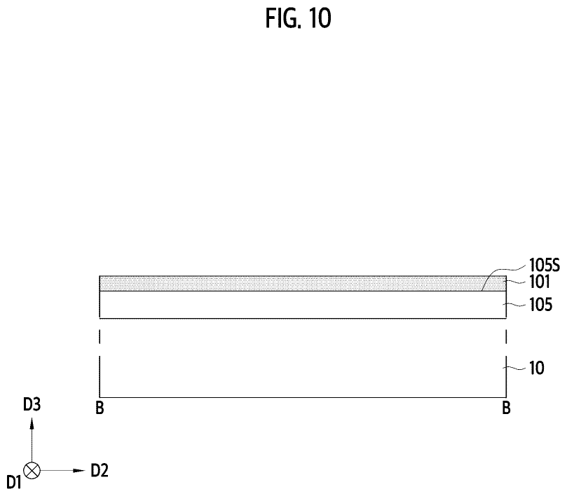

Referring to FIG. 9 and FIG. 10, a cover liner 101 may be formed. The cover liner 101 may be formed to extend in the second direction D2 along the surface 105S of the first molding structure 105 between the plurality of protruding patterns 105p. The cover liner 101 may not form on the side of the plurality of protruding patterns 105p. The cover liner 101 may cover the surface 105S of the first molding structure 105 between the plurality of protruding patterns 105p in the first direction D1. The cover liner 101 may include, for example, polysilicon.

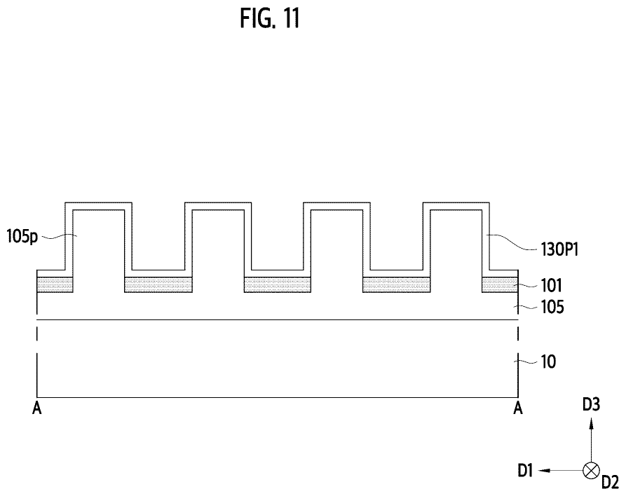

Referring to FIG. 11, a first pre-gate insulating film 130P1 may be formed. The first pre-gate insulating film 130P1 may be extended along the plurality of protruding patterns 105p and the profile of the cover liner 101. The first pre-gate insulating film 130P1 may be formed on the side surfaces of the plurality of protruding patterns 105p, the upper surfaces of the plurality of protruding patterns 105p, and the upper surfaces of the cover liner 101. The first pre-gate insulating film 130P1 may contain, for example, hafnium oxide.

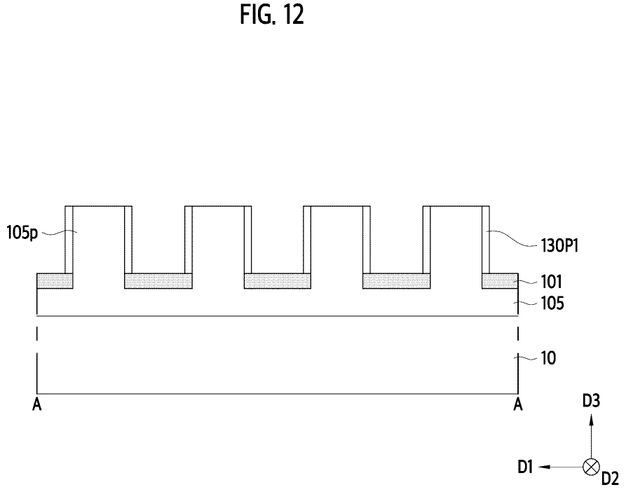

Referring to FIG. 12, the first pre-gate insulating film 130P1 on the upper surfaces of the plurality of protruding patterns 105P and upper surfaces of the cover liner may be removed. Through the etch back process, the first pre-gate insulating film 130P1 on the upper surfaces of the plurality of protruding patterns 105p and the upper surfaces of the cover liner 101 may be removed. The first pre-gate insulating film 130P1 may cover the sides of a plurality of protruding patterns 105p, but not the upper surfaces of the plurality of protruding patterns 105p and the upper surfaces of the cover liner 101.

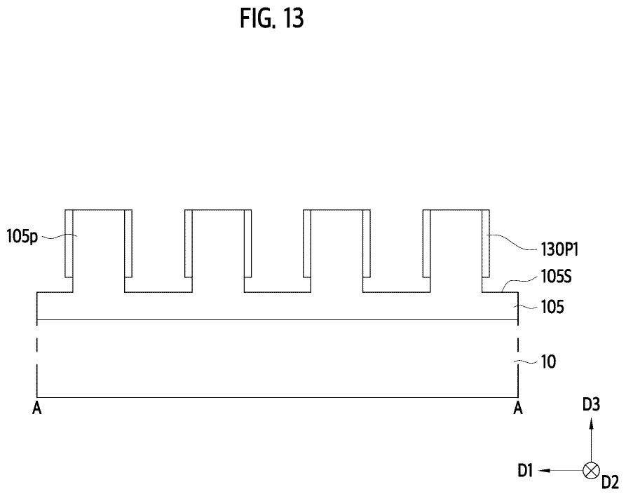

Referring to FIG. 13, the cover liner 101 (of FIG. 12) may be removed. When the cover liner 101 (of FIG. 12) is removed, the surface 105S of the first molding structure 105 may be exposed. The first pre-gate insulating film 130P1 and the surface 105S of the first molding structure 105 may be spaced apart in the third direction D3. With respect to the lower portion of the first pre-gate insulating film 130P1, a portion of a side of each of the plurality of protruding patterns 105p may be exposed.

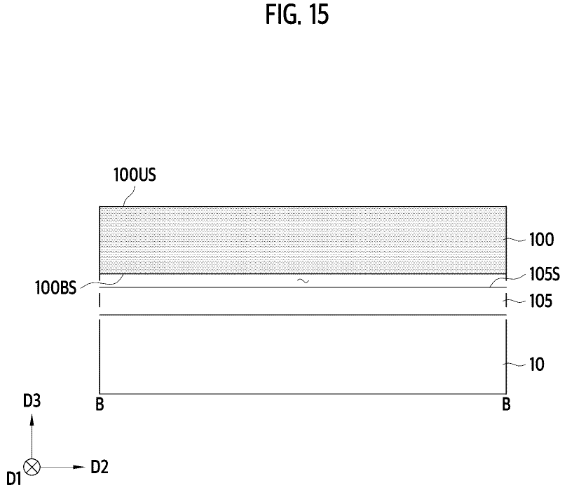

Referring to FIG. 14 and FIG. 15, the plurality of channel layers 100 may be formed on the first pre-gate insulating film 130P1. The plurality of channel layers 100 may be formed on the side surface of the first pre-gate insulating film 130P1 placed in the first direction D1. For example, the first pre-gate insulating film 130P1 may be used as a base substrate on which the plurality of channel layers 100 are grown. The plurality of channel layers 100 may be formed only on the surface of the first pre-gate insulating film 130P1, and the plurality of channel layers 100 may not be formed on the side surface of the plurality of protruding patterns 105p and the surface 105S of the first molding structure 105 exposed in the lower portion of the first pre-gate insulating film 130P1.

According to some example embodiments, with respect to the material included in the plurality of channel layers 100, the bond energy (e.g., binding energy or bond strength) for the material contained in the first pre-gate insulating film 130P1 may be greater than the bond energy for the material contained in the first molding structure 105. Therefore, the plurality of channel layers 100 may be selectively formed on the side surface of the first pre-gate insulating film 130P1, but the plurality of channel layers 100 may not be formed at sides of the plurality of protruding patterns 105p exposed at a surface 105S of the first molding structure 105 and the lower portion of the first pre-gate insulating film 130P1. Therefore, the bottom surfaces 100BS of the plurality of channel layers 100 and the surface 105S of the first molding structure 105 may be spaced apart in the third direction D3.

According to some example embodiments, the plurality of channel layers 100 may include a material in which the bond energy for the material contained in the first pre-gate insulating film 130P1 is relatively higher than the bond energy for the material contained in the first molding structure 105 among 2D materials.

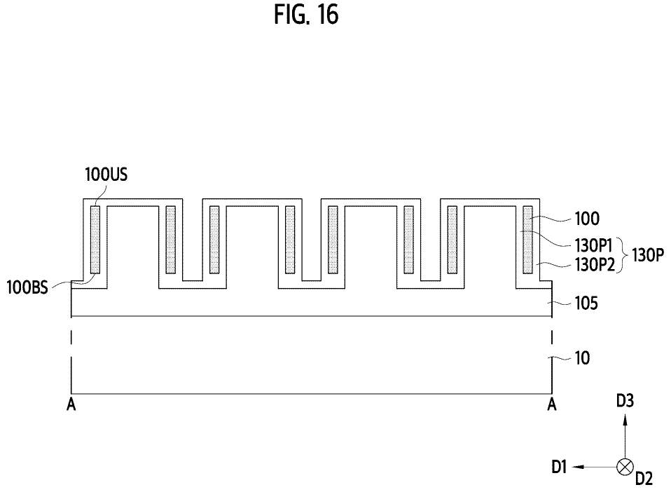

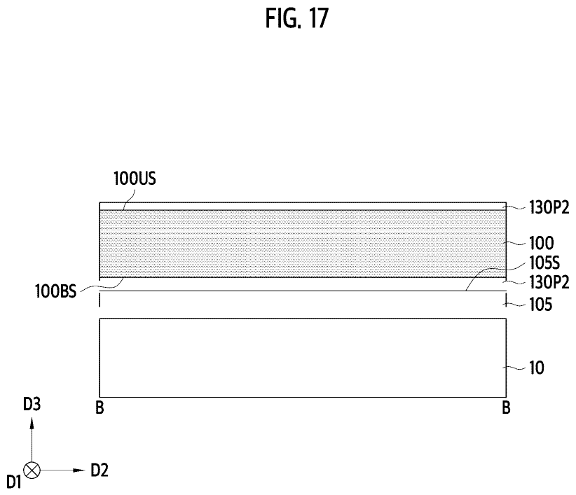

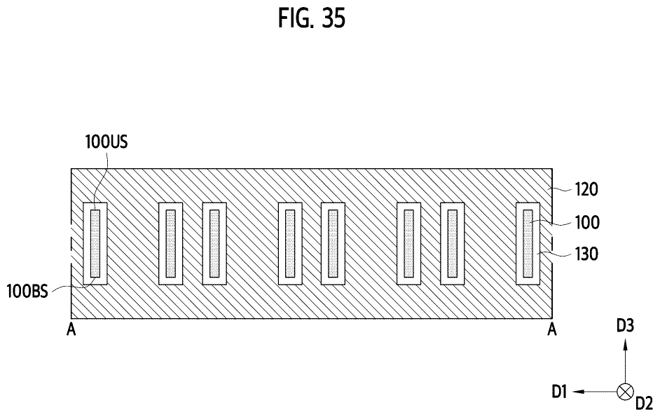

Referring to FIG. 16 and FIG. 17, a second pre-gate insulating film 130P2 may be formed. The second pre-gate insulating film 130P2 may be connected to the first pre-gate insulating film 130P1. The second pre-gate insulating film 130P2 may contain the same material as the first pre-gate insulating film 130P1. The second pre-gate insulating film 130P2 may extend along the profile of the first molding structure 105, the first pre-gate insulating film 130P1 and the plurality of channel layers 100. The second pre-gate insulating film 130P2 may cover the upper surfaces 100US of the plurality of channel layers 100 and the bottom surfaces 100BS of the plurality of channel layers 100. The second pre-gate insulating film 130P2 may fill between the bottom surfaces 100BS of the plurality of channel layers 100 and the surface 105S of the first molding structure 105. The plurality of channel layers 100 may be surrounded by a pre-gate insulating film 130P. The first pre-gate insulating film 130P1 may be used as a base substrate on which the plurality of channel layers 100 are grown. Further, the first pre-gate insulating film 130P1 may be used as an insulating film for the gate electrode 120 formed later (e.g., see FIG. 35) together with the second pre-gate insulating film 130P2.

According to some example embodiments, in the third direction D3, the thickness of the second pre-gate insulating film 130P2 placed between the bottom surfaces 100BS of the plurality of channel layers 100 and the surface 105S of the first molding structure 105 may be greater than the thickness of the second pre-gate insulating film 130P2 formed on the upper surfaces 100US of the plurality of channel layers 100.

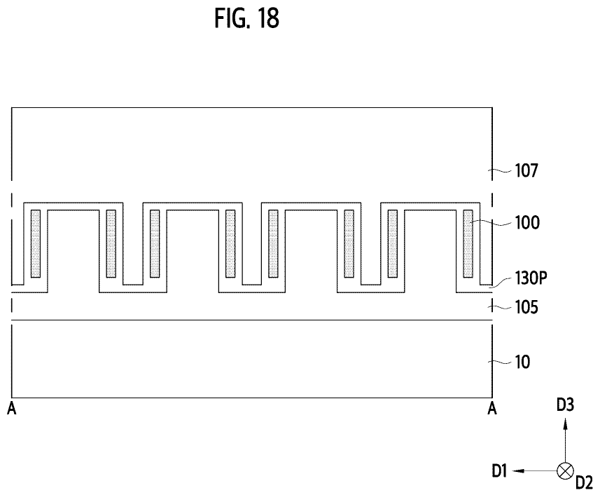

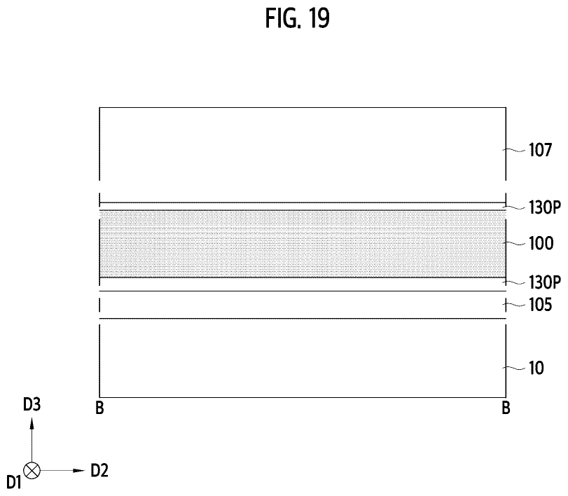

Referring to FIG. 18 and FIG. 19, a second molding structure 107 may be formed. The second molding structure 107 may be formed on the pre-gate insulating film 130P. The second molding structure 107 may cover the pre-gate insulating film 130P. The second molding structure 107 may include polysilicon, for example.

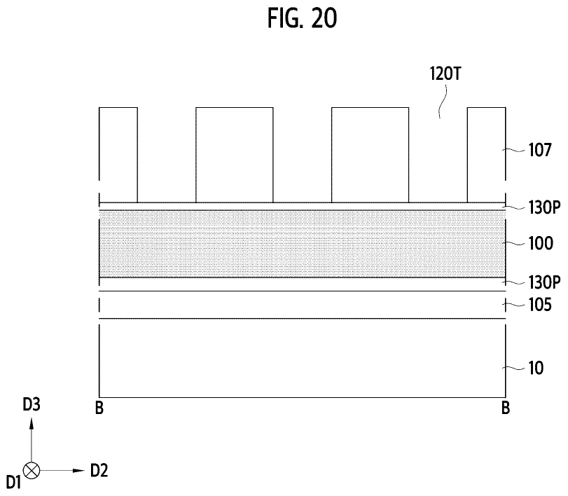

Referring to FIG. 20, a gate electrode trench 120T may be formed. The gate electrode trench 120T may be formed by partially removing the second molding structure 107. The gate electrode trench 120T may penetrate the second molding structure 107. The pre-gate insulating film 130P may be exposed within the gate electrode trench 120T.

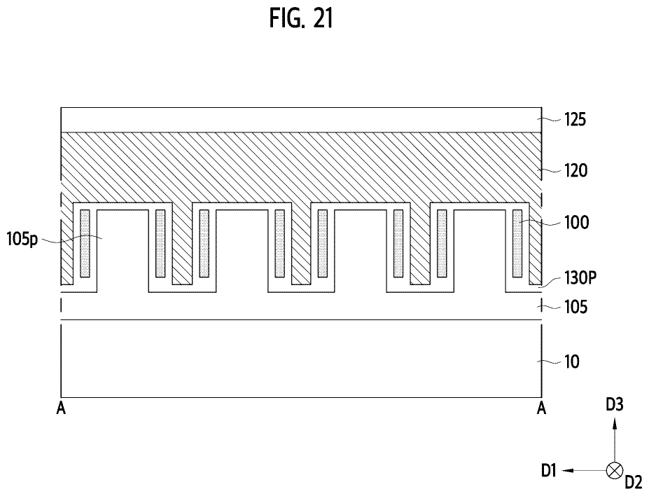

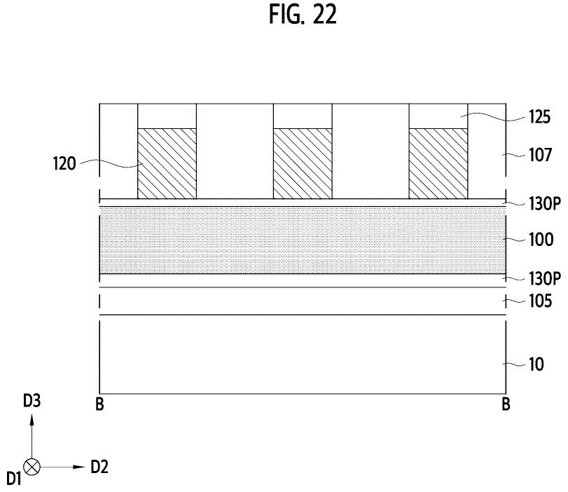

Referring to FIG. 21 and FIG. 22, the gate electrode 120 may be formed within and covering the gate electrode trench 120T (of FIG. 20). A capping film 125 may be formed on the gate electrode 120. For example, the capping film 125 may include at least one of silicon nitride (SiN), silicon oxynitride (SiON), silicon carbonitride (SiCN), silicon oxycarbonitride (SiOCN), or any combination thereof. The gate electrode 120 may fill the space between the plurality of protruding patterns 105p adjacent in the first direction D1 on the pre-gate insulating film 130P.

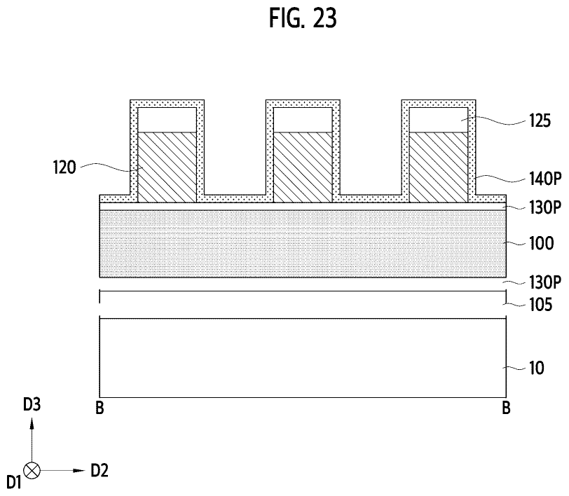

Referring to FIG. 23, the second molding structure 107 (in FIG. 22) is removed, and a first pre-gate spacer 140P may be formed. The first pre-gate spacer 140P may extend along the profile of the pre-gate insulating film 130P, the gate electrode 120, and the capping film 125. The first pre-gate spacer 140P may cover the upper surface of the capping film 125. The first pre-gate spacer 140P may contain silicon oxycarbonitride (SiOCN), for example.

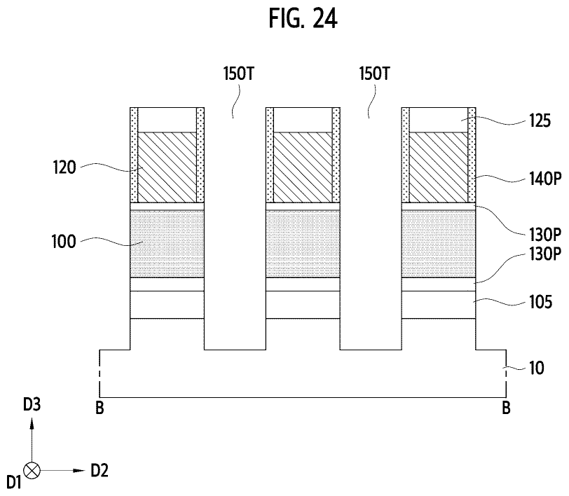

Referring to FIG. 24, a source/drain pattern trench 150T may be formed using the first pre-gate spacer 140P placed on the side of the gate electrode 120 as a mask. The source/drain pattern trench 150T may be formed by removing a portion of the plurality of channel layers 100, a portion of a pre-gate insulating film 130P, a portion of the first molding structure 105 and a portion of the substrate 10. As the source/drain pattern trench 150T is formed, the first pre-gate spacer 140P covering the upper surface of the capping film 125 may be removed.

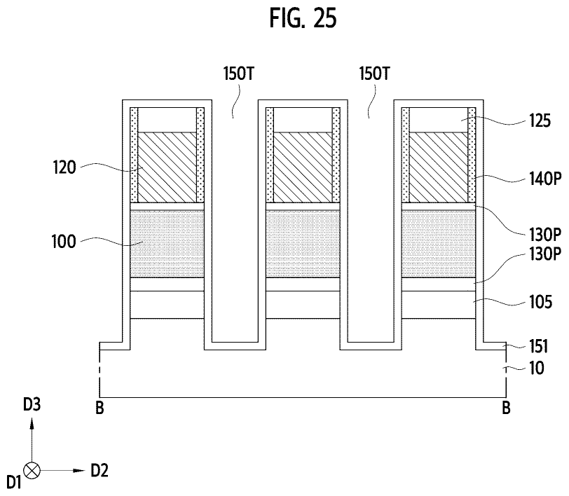

Referring to FIG. 25, a first protecting film 151 may be formed. The first protecting film 151 may extend along the profile of the source/drain pattern trench 150T and the upper surface of the capping film 125. Within the source/drain pattern trench 150T, the first protecting film 151 may cover the first molding structure 105, the pre-gate insulating film 130P, the plurality of channel layers 100, and the first pre-gate spacer 140P. The first protecting film 151 may include silicon nitride (SiN), for example.

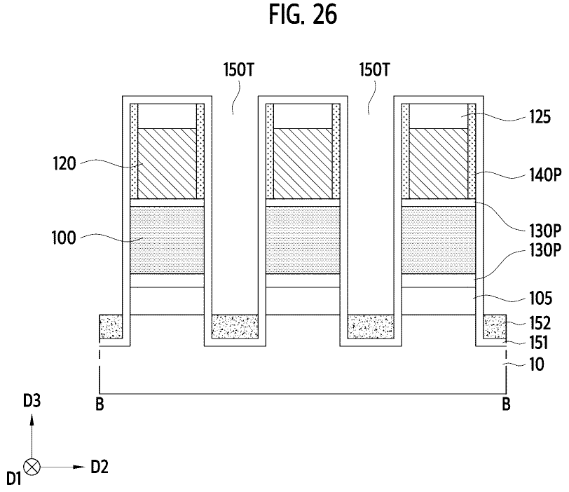

Referring to FIG. 26, a second protecting film 152 may be formed on the first protecting film 151. The second protecting film 152 may cover a portion of the first protecting film 151 within the source/drain pattern trench 150T. The second protecting film 152 may be formed at the lower portion of the first molding structure 105. The second protecting film 152 may not overlap the first molding structure 105 in the second direction D2. The second protecting film 152 may include, for example, spin on hardmask (SOH).

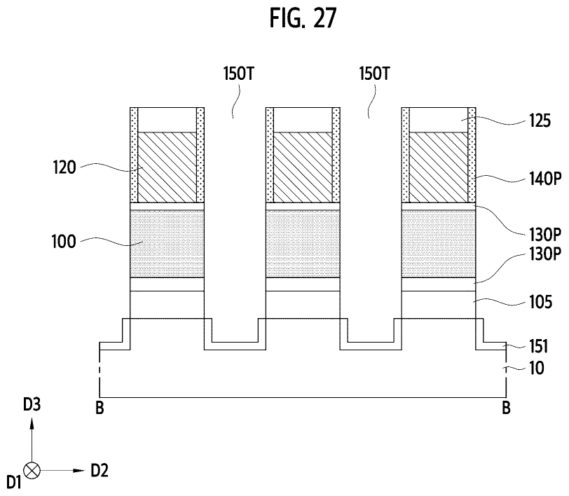

Referring to FIG. 27, the remaining part of the first protecting film 151, excluding a part of the first protecting film 151 covered by the second protecting film 152 (of FIG. 26) and the second protecting film 152 (in FIG. 26) may be removed. Within the source/drain pattern trench 150T, the first molding structure 105, a portion of the pre-gate insulating film 130P, a portion of the plurality of channel layers 100, and a portion of the first pre-gate spacer 140P may be exposed.

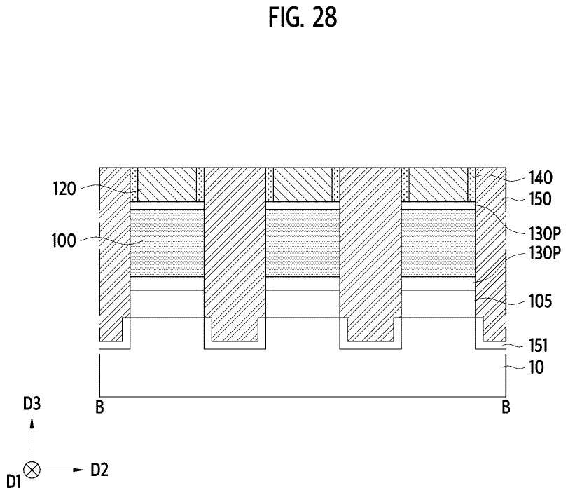

Referring to FIG. 28, the source/drain pattern 150 may be formed, and the gate electrode 120 and the first gate spacer 140 may be polished. The source/drain pattern 150 may fill the source/drain pattern trench 150T (in FIG. 27). The source/drain pattern 150, the gate electrode 120 and the first gate spacer 140 may be polished simultaneously. For example, the source/drain pattern 150, the gate electrode 120, and the first gate spacer 140 may be polished through a chemical mechanical polishing/planarization (CMP). The capping film 125 (in FIG. 27) may be removed through a polishing/planarization process. However, example embodiments are not limited thereto. By controlling the amount of being polished, the capping film 125 (of FIG. 27) may not be completely removed and may remain on the gate electrode 120.

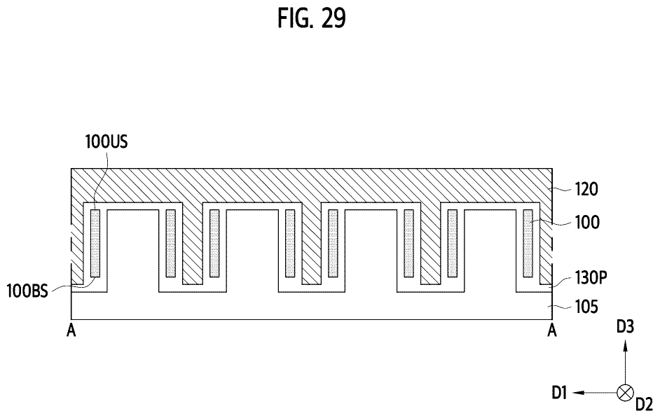

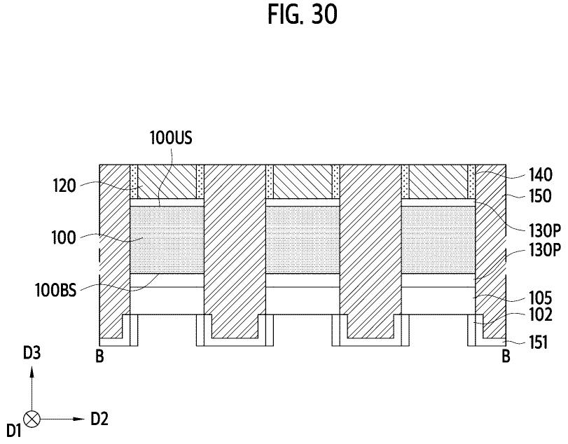

Referring to FIG. 29 and FIG. 30, the substrate 10 (of FIG. 28) may be removed and an align spacer 102 may be formed. As the substrate 10 (of FIG. 28) is removed, the first molding structure 105 may be exposed on the lower portion of the bottom surfaces 100BS of the plurality of channel layers 100. The align spacer 102 may be formed on the side of the first protecting film 151 in the second direction D2. The align spacer 102 may overlap the first gate spacer 140 in the third direction D3. The align spacer 102 may be formed in the lower portion of the first molding structure 105. The align spacer 102 may overlap part of the first molding structure 105.

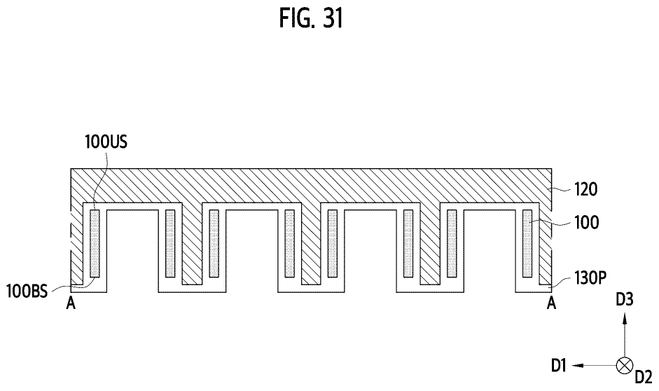

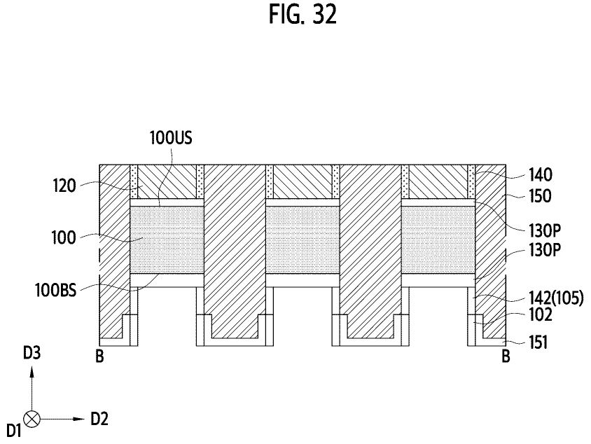

Referring to FIG. 31 and FIG. 32, the first molding structure 105 (of FIG. 29) may be removed. For example, the first molding structure 105 (of FIG. 29) placed at the lower portion of the pre-gate insulating film 130P may be removed. The pre-gate insulating film 130P may be exposed at the lower portion. The first molding structure 105 (of FIG. 29) may be patterned using the align spacer 102 between the source/drain pattern 150 in the second direction D2 to form the second gate spacer 142. The first molding structure 105 (of FIG. 29) may be removed between the align spacers 102 that are spaced apart in the second direction D2, so that the bottom surface of the pre-gate insulating film 130P may be exposed.

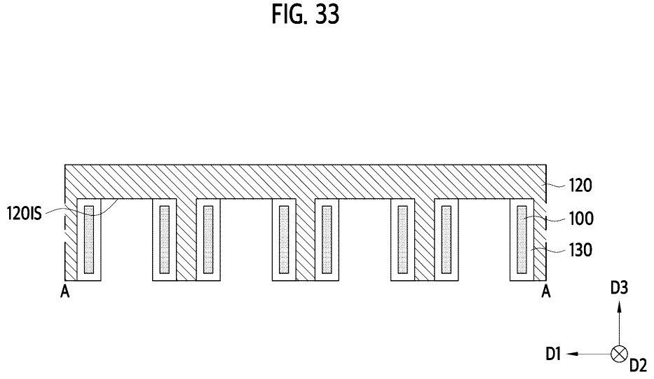

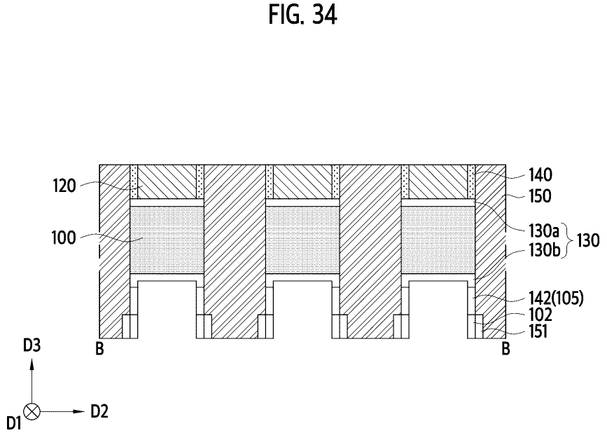

Referring to FIG. 33 and FIG. 34, a portion of the pre-gate insulating film 130P (in FIG. 31 and FIG. 32) may be removed to form the gate insulating film 130. A portion of the pre-gate insulating film 130P (in FIG. 31 and FIG. 32) may be removed to expose inner surfaces 120IS of the gate electrode 120. A portion of the pre-gate insulating film 130P (of FIG. 31 and FIG. 32) may be removed between the second gate spacers 142 in the second direction D2 in order for the bottom surface part 130b of the gate insulating film 130 to be formed.

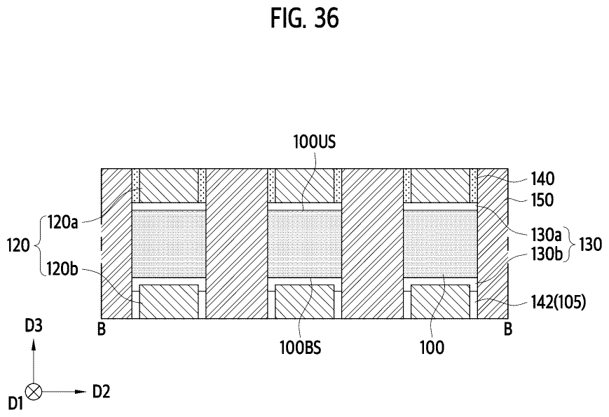

Referring to FIG. 35 and FIG. 36, the gate electrode 120 may be formed to fill a space between the lower portion of the bottom surfaces 100BS of the plurality of channel layers 100 and the plurality of channel layers 100 spaced apart in the first direction D1. The first protecting film 151 (in FIG. 34) and the align spacer 102 (in FIG. 34) may be removed through the polishing/planarization process. The remaining part of the gate electrode 120 may be formed in order to cover the lower portion of the bottom surfaces 100BS of the plurality of channel layers 100 and the inner surfaces 120IS of the gate electrode 120 between the plurality of channel layers 100 spaced apart in the first direction D1.

Further, referring to FIG. 2 and FIG. 3, formed may be frontside interlayer insulating films (the first frontside interlayer insulating film 191 and the second frontside interlayer insulating film 192), the frontside gate contact 170, the frontside source/drain contact 180, the backside interlayer insulating films (the first backside interlayer insulating film 291 and the second backside interlayer insulating film 292), the backside gate contact 270 and the backside source/drain contact 280.

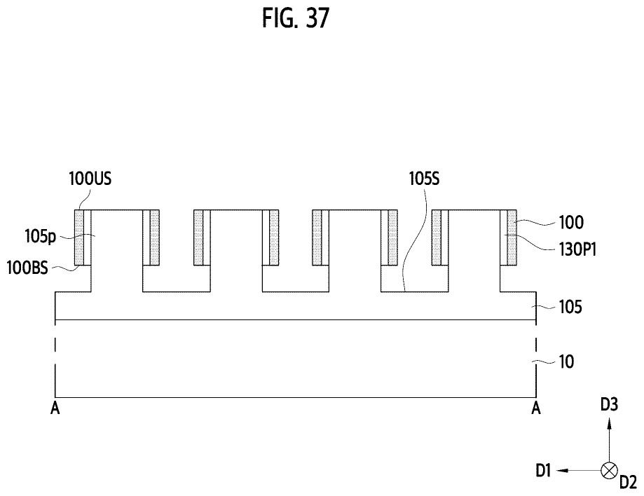

FIG. 37 to FIG. 52 are drawings illustrating intermediate operations for explaining a method for manufacturing a semiconductor device illustrated in FIG. 4 and FIG. 5. The differences from those described with reference to FIG. 7 to FIG. 36 will be mainly explained to explain the semiconductor device according to some other example embodiments.

Referring to FIG. 37, the plurality of channel layers 100 on the side of the plurality of protruding patterns 105p may be formed on the side of the first pre-gate insulating film 130P1 placed in the first direction D1. The plurality of channel layers 100 may be formed only on the surface of the first pre-gate insulating film 130P1, and the plurality of channel layers 100 may not be formed on the side surface of the plurality of protruding patterns 105p and the surface 105S of the first molding structure 105 exposed in the lower portion of the first pre-gate insulating film 130P1. Referring to FIG. 37 in comparison with FIG. 14, the distance between the surface 105S of the first molding structure 105 and the bottom surfaces 100BS of the plurality of channel layers 100 in the third direction D3 may be greater.

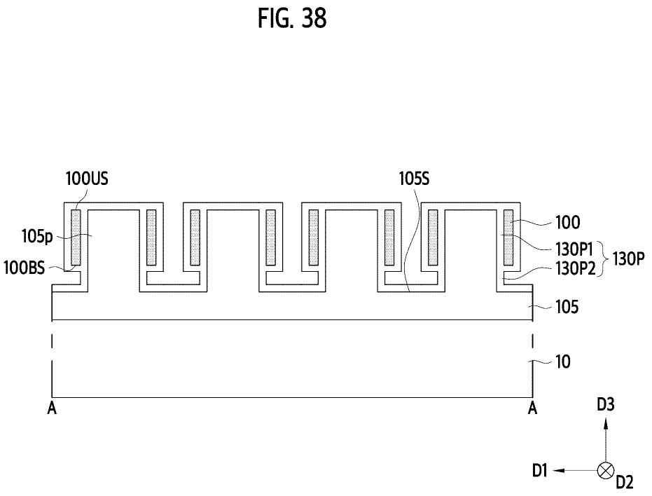

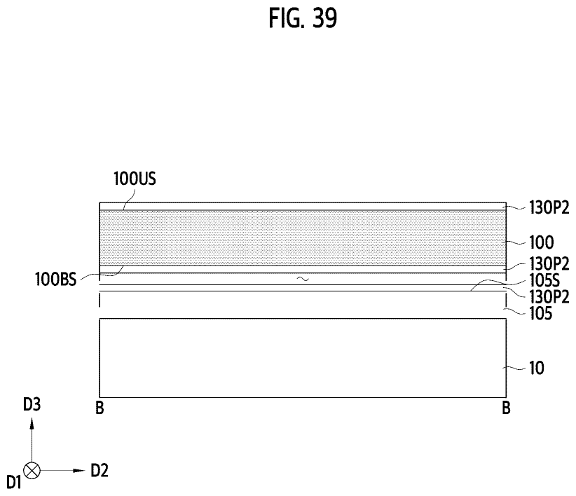

Referring to FIG. 38 and FIG. 39, the second pre-gate insulating film 130P2 may extend along the profile of the first molding structure 105, the first pre-gate insulating film 130P1 and the plurality of channel layers 100. The second pre-gate insulating film 130P2 may extend along the side of the plurality of protruding patterns 105p. The second pre-gate insulating film 130P2 covering the bottom surfaces 100BS of the plurality of channel layers 100 and the second pre-gate insulating film 130P2 covering the surface 105S of the first molding structure 105 may be spaced apart in the third direction D3. This may be due to the relatively large distance between the surface 105S of the first molding structure 105 and the bottom surfaces 100BS of the plurality of channel layers 100 in the third direction D3.

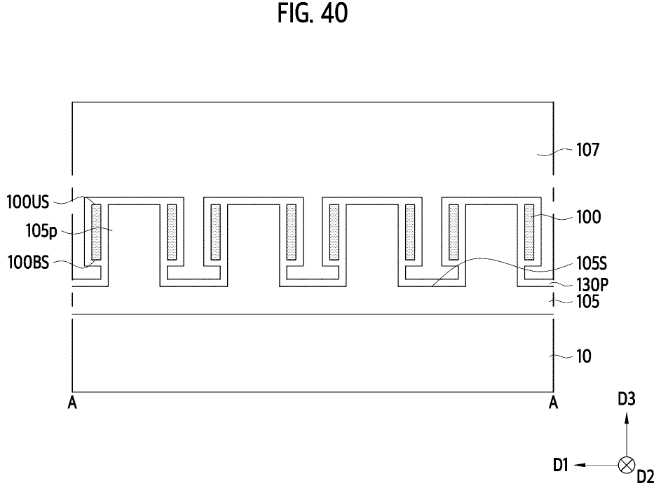

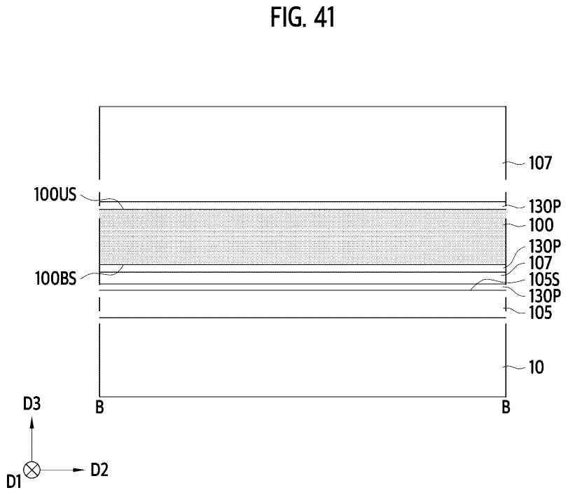

Referring to FIG. 40 and FIG. 41, the second molding structure 107 may fill the space between the second pre-gate insulating film 130P2 covering the bottom surfaces 100BS of the plurality of channel layers 100 and the second pre-gate insulating film 130P2 covering the surface 105S of the first molding structure 105. For example, the second molding structure 107 between the plurality of protruding patterns 105p in the first direction D1 may have a “T” shape rotated 180 degrees. The second molding structure 107 may be formed on the lower portion of the bottom surfaces 100BS of the plurality of channel layers 100.

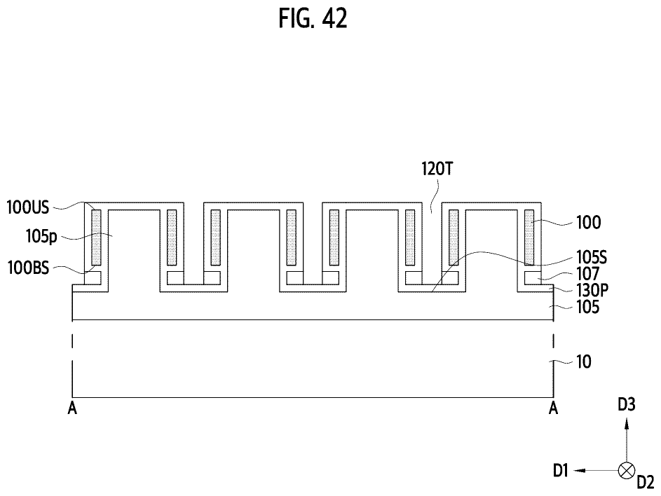

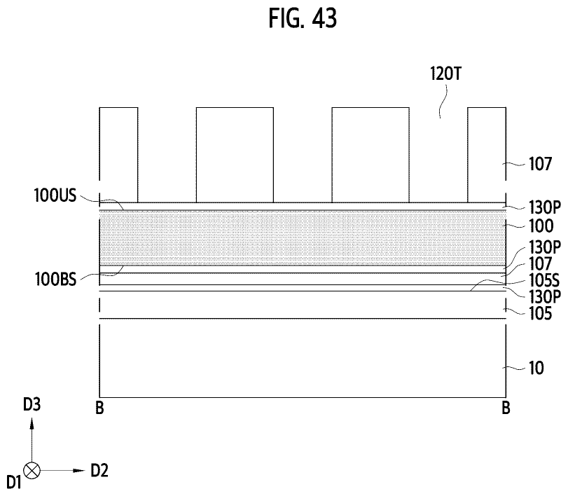

Referring to FIG. 42 and FIG. 43, the gate electrode trench 120T may be formed. A portion of the second molding structure 107 may be removed to expose the pre-gate insulating film 130P between the plurality of protruding patterns 105p. The second molding structure 107 filling the space between the pre-gate insulating film 130P covering the bottom surfaces 100BS of the plurality of channel layers 100 and the pre-gate insulating film 130P covering the surface 105S of the first molding structure 105 may not be removed. The gate electrode trench 120T may be formed between the second molding structures 107 that are not removed in the first direction D1. The second molding structure 107 between the pre-gate insulating film 130P covering the bottom surfaces 100BS of the plurality of channel layers 100 and the pre-gate insulating film 130P covering the surface 105S of the first molding structure 105 may be extended in the second direction D2.

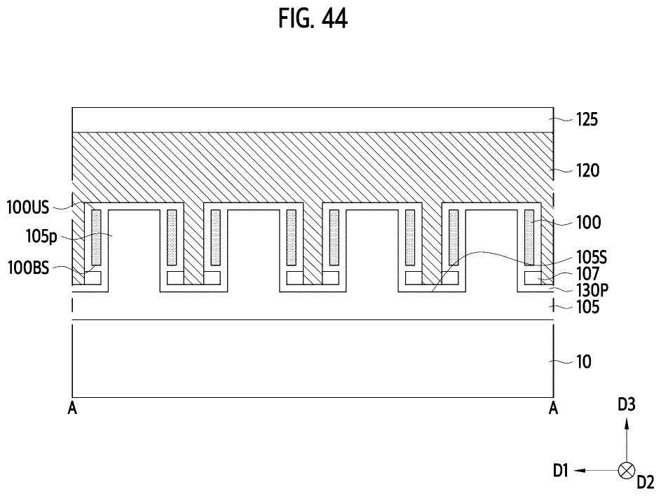

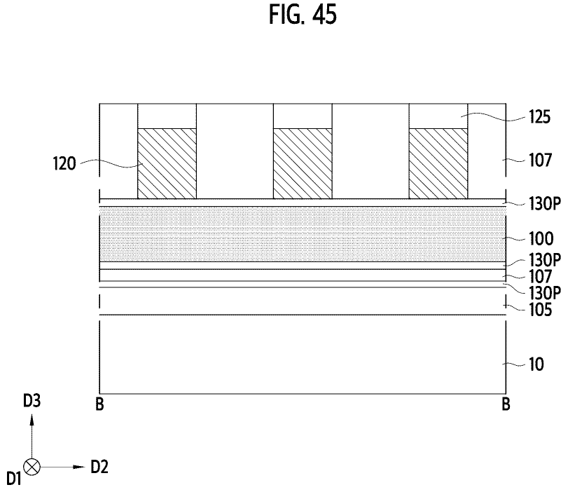

Referring to FIG. 44 and FIG. 45, the gate electrode 120 and the capping film 125 may be formed. In the first direction D1, the gate electrode 120 may be placed between the second molding structures 107 filling the space between the pre-gate insulating film 130P covering the bottom surfaces 100BS of the plurality of channel layers 100 and the pre-gate insulating film 130P covering the surface 105S of the first molding structure 105.

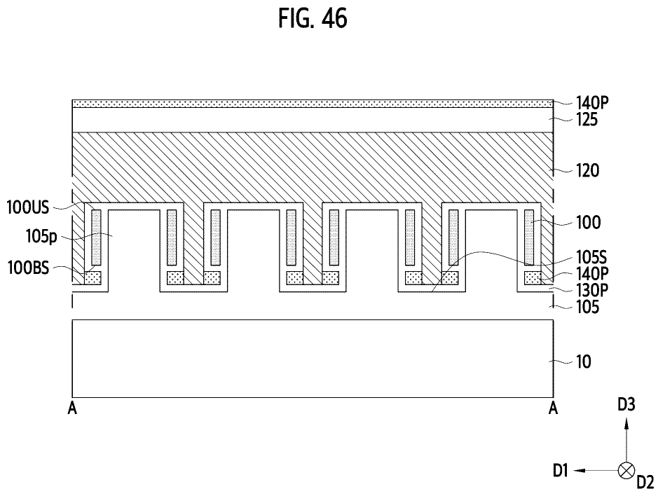

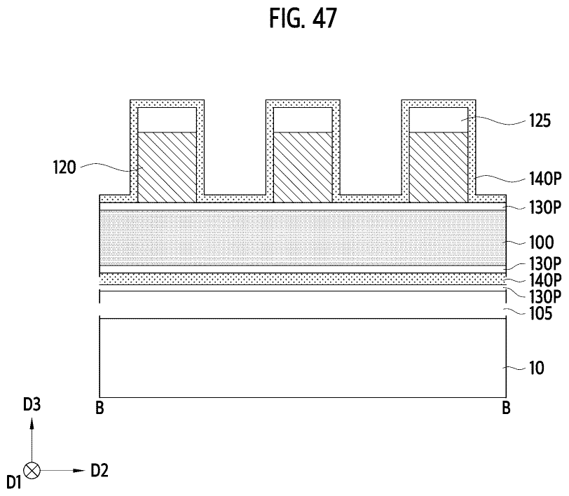

Referring to FIG. 46 and FIG. 47, the second molding structure 107 (in FIG. 44 and FIG. 45) is removed, and the first pre-gate spacer 140P is formed. The first pre-gate spacer 140P may be formed in the space between the pre-gate insulating films 130P covering the bottom surfaces 100BS of the plurality of channel layers 100 and the pre-gate insulating films 130P covering the surface 105S of the first molding structure 105. In the lower portion of the plurality of channel layers 100, the first pre-gate spacer 140P may overlap with the plurality of channel layers 100 and the pre-gate insulating film 130P in the third direction D3. At the lower portion of the plurality of channel layers 100, the first pre-gate spacer 140P may be placed between the pre-gate insulating films 130P in the third direction D3. The first pre-gate spacer 140P disposed between the pre-gate insulating films 130P in the lower portion of the plurality of channel layers 100 in the third direction D3 may extend in the second direction D2.

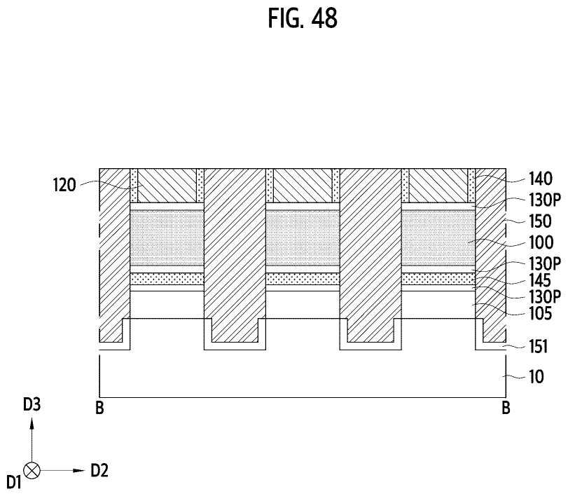

Referring to FIG. 48, when the source/drain pattern 150 is formed, the first pre-gate spacer 140P (of FIG. 47) placed between the pre-gate insulating films 130P along the third direction D3 may be cut to be placed between the source/drain patterns 150 in the second direction D2. The first pre-gate spacer 140P (in FIG. 47) may be cut by the source/drain pattern 150 to form the dummy spacer 145. The dummy spacer 145 may contain the same material as the first gate spacer 140.

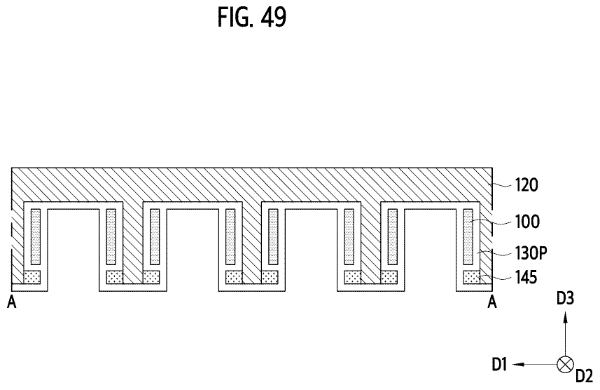

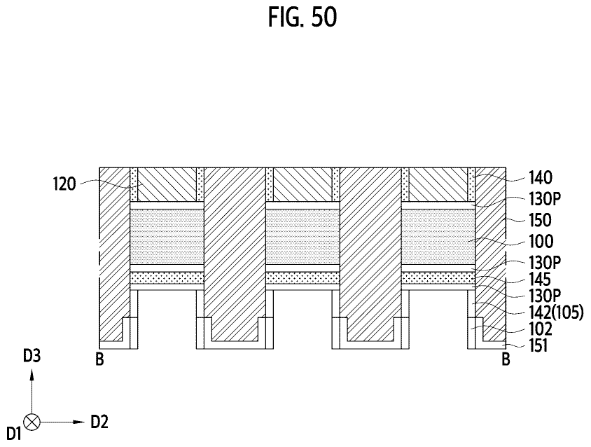

Referring to FIG. 49 and FIG. 50, the substrate 10 (of FIG. 48) may be removed, and the align spacer 102 may be formed on the side of the first protecting film 151. Further, the first molding structure 105 (in FIG. 46 and FIG. 48) may be removed. The first molding structure 105 (of FIG. 46 and FIG. 48) may be removed between the plurality of channel layers 100 in the first direction D1. The first molding structure 105 (of FIG. 46 and FIG. 48) may be patterned using the align spacer 102 between the source/drain pattern 150 in the second direction D2 to form the second gate spacer 142.

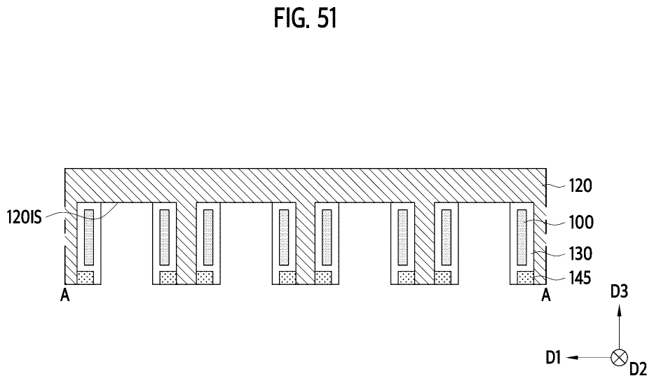

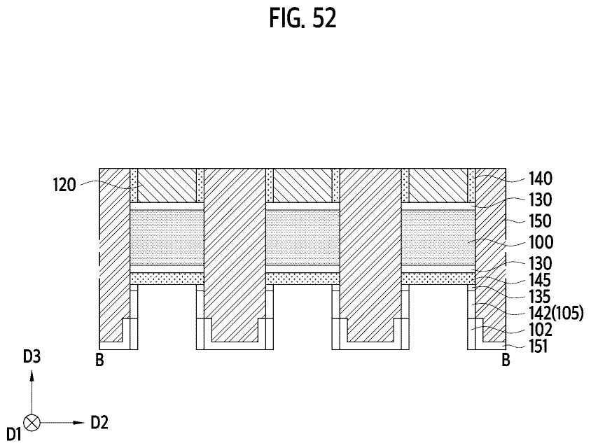

Referring to FIG. 51 and FIG. 52, a portion of the pre-gate insulating film 130P (in FIG. 49 and FIG. 50) may be removed to form the gate insulating film 130. A portion of the pre-gate insulating film 130P (in FIG. 49 and FIG. 50) may be removed to expose the inner surfaces 120IS of the gate electrode 120. The pre-gate insulating film 130P (in FIG. 49 and FIG. 50) placed on the lower portion of the dummy spacer 145 may be patterned using the align spacer 102 and the second gate spacer 142 to form the protruding part 135.

The operations after FIG. 51 and FIG. 52 are substantially the same as the operations described with reference to FIG. 35 and FIG. 36, and are therefore omitted.

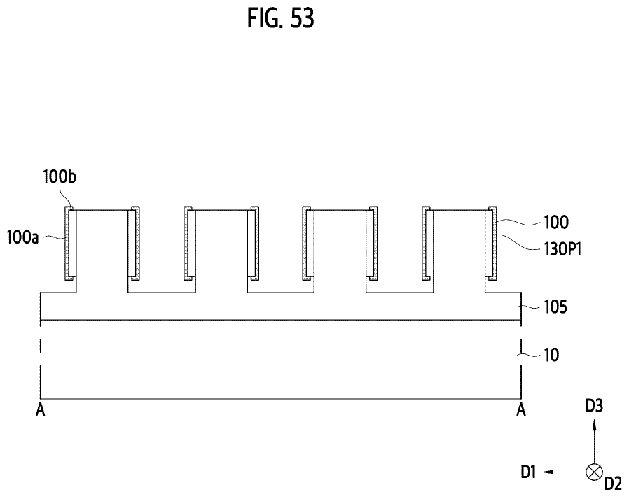

FIG. 53 to FIG. 58 are drawings illustrating intermediate operations for explaining a method for manufacturing a semiconductor device illustrated in FIG. 6. The differences from those described with reference to FIG. 7 to FIG. 36 will be mainly explained to explain the semiconductor device according to some other example embodiments.

Referring to FIG. 53, the plurality of channel layers 100 may be formed on the side surface of the first pre-gate insulating film 130P1 in the first direction D1. The plurality of channel layer 100 may cover a portion of the upper surface of the first pre-gate insulating film 130P1 and a portion of the bottom surface of the first pre-gate insulating film 130P1 so as not to come into contact with the first molding structure 105. The thickness of the plurality of channel layers 100 may be less than the thickness of the first pre-gate insulating film 130P1. Therefore, the plurality of channel layers 100 may be formed extending along not only the side of the first pre-gate insulating film 130P1, but also the portion of the upper surface of the first pre-gate insulating film 130P1 and the portion of the bottom surface of the first pre-gate insulating film 130P1. The plurality of channel layers 100 may include the extended part 100a covering the side surface of the first pre-gate insulating film 130P1, and the bent part 100b covering the portion of the upper surface of the first pre-gate insulating film 130P1 and the portion of the bottom surface of the first pre-gate insulating film 130P1.

According to some example embodiments, the plurality of channel layers 100 may include a material in which the bond energy for the material contained in the first pre-gate insulating film 130P1 may be greater than the bond energy for the material contained in the first molding structure 105. Therefore, the plurality of channel layers 100 may be formed along the surface profile of the first pre-gate insulating film 130P1, without contacting the first molding structure 105.

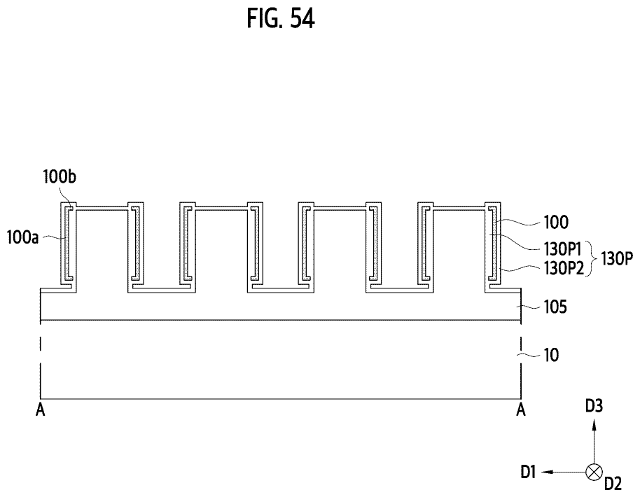

Referring to FIG. 54, the second pre-gate insulating film 130P2 may be formed. The second pre-gate insulating film 130P2 may be connected to the first pre-gate insulating film 130P1. The second pre-gate insulating film 130P2 may be formed along the first molding structure 105 and the surface profile of the extended part 100a and the bent part 100b of the plurality of channel layers 100.

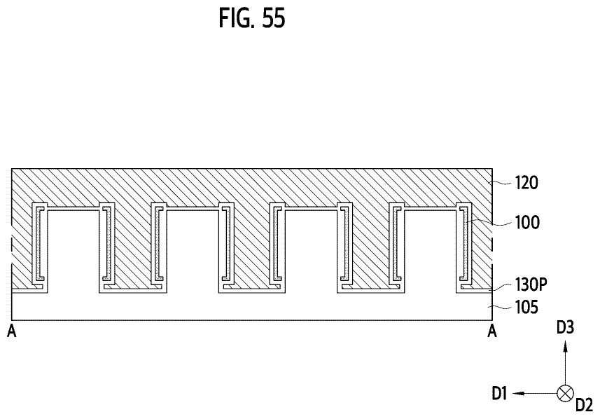

Referring to FIG. 55, the gate electrode 120 is formed on the first molding structure 105, and the substrate 10 (of FIG. 54) may be removed.

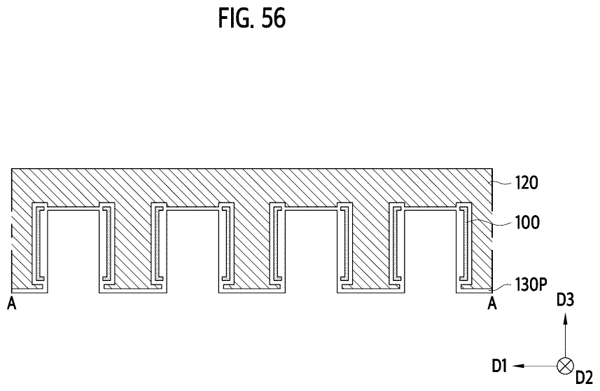

Referring to FIG. 56, the first molding structure 105 (in FIG. 55) may be removed.

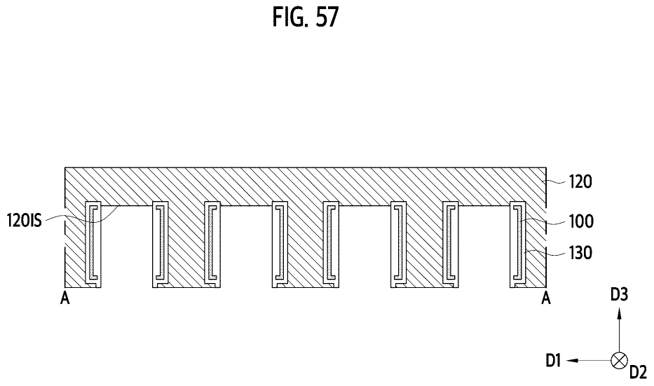

Referring to FIG. 57, a portion of the pre-gate insulating film 130P (of FIG. 56) may be removed to form the gate insulating film 130. A portion of the pre-gate insulating film 130P (in FIG. 56) may be removed to expose the inner surfaces 120IS of the gate electrode 120.

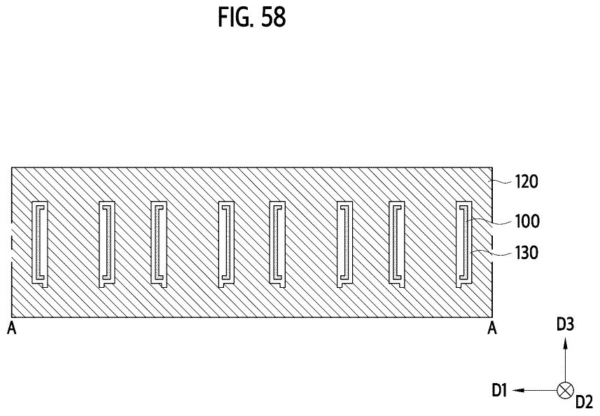

Referring to FIG. 58, the gate electrode 120 may be formed to fill the space between the lower portion of the bottom surfaces of the plurality of channel layers 100 and the plurality of channel layers 100 that are spaced apart in the first direction D1. The remaining portion of the gate electrode 120 may be formed to cover the inner surfaces 120IS (of FIG. 57) of the gate electrode 120.

The operations after FIG. 58 are substantially the same as the operations described with reference to FIG. 35 and FIG. 36, and are therefore omitted.

According to example embodiments, it is possible to improve the integration density of semiconductor devices and improve the electrical contact for densely integrated 2D (e.g., atomically thin) channel layers within semiconductor devices.

In the above, various embodiments of the present disclosure are described in detail. However, it will be apparent to those with average knowledge in the technical field that scope of rights of this disclosure is not limited thereto, and various modifications and variations are possible without departing from the technical spirit of the present disclosure as set forth in the claims. Further, the above-described example embodiment may be implemented with some elements deleted, and each example embodiment may be implemented in combination with each other.

1. A semiconductor device comprising:
a gate electrode extending lengthwise in a first direction;
a plurality of channel layers that penetrate the gate electrode in a second direction intersecting the first direction, and are spaced apart in the first direction; and
a gate insulating film including a plurality of gate insulating film patterns, each gate insulating film pattern at least partially covering a respective channel layer of the plurality of channel layers,
wherein a height of each respective channel layer of the plurality of channel layers in a third direction intersecting the first direction and the second direction is greater than a width of the respective channel layer in the first direction.

2. The semiconductor device of claim 1, wherein the plurality of channel layers comprise upper surfaces and lower surfaces that are positioned along the third direction, and
wherein each gate insulating film pattern covers a respective upper surface and a respective lower surface of one respective channel layer and covers side surfaces of the one respective channel layer extending between the respective upper surface and the respective lower surface.

3. (canceled)

4. The semiconductor device of claim 1, wherein none of the plurality of channel layers overlap others of the plurality of channel layers in the third direction.

5. The semiconductor device of claim 1, wherein the plurality of channel layers comprise one or more of:
MoS2;
MoSe2;
MoTe2;
WS2;
WSe2;
MoTe2;
PtSe2;
another transition metal dichalcogenide (TMD); or
another 2 dimensional (2D) or atomically thin material.

6. The semiconductor device of claim 1, wherein each of the plurality of channel layers comprises:
an extended part which extends in the third direction; and
a bent part that is bent from the extended part in the first direction.

7. The semiconductor device of claim 1, wherein the plurality of channel layers comprise upper surfaces and lower surfaces that are positioned along the third direction, and wherein the gate electrode comprises:
a first gate electrode part that is placed on each of the upper surfaces of the plurality of channel layers in the third direction; and
a second gate electrode part that is placed beneath each of the lower surfaces of the plurality of channel layers in the third direction,
wherein the first gate electrode part does not overlap the gate insulating film in the second direction, and
at least a portion of the second gate electrode part overlaps the gate insulating film in the second direction.

8. The semiconductor device of claim 7, wherein the first gate electrode part comprises a first facing surface that faces each of the upper surfaces of the plurality of channel layers,
wherein the second gate electrode part comprises a second facing surface that faces each of the lower surfaces of the plurality of channel layers, and
wherein the gate insulating film comprises a protruding part that protrudes further downward to a lower surface of each gate electrode than the second facing surface.

9. The semiconductor device of claim 7, further comprising:
a first gate spacer that covers a side of the first gate electrode part along the second direction; and
a second gate spacer that covers a side of the second gate electrode part along the second direction.

10. The semiconductor device of claim 9, wherein a bond energy of a material included in the plurality of channel layers to a material included in the gate insulating film is greater than a bond energy of the material included in the plurality of channel layers to a material included in the second gate spacer.

11. The semiconductor device of claim 9, wherein the first gate spacer and the second gate spacer each comprise different materials.

12. The semiconductor device of claim 1, further comprising a spacer that is placed between one of the plurality of channel layers and the gate electrode in the third direction, and contacts the gate insulating film and the gate electrode.

13. The semiconductor device of claim 12, wherein the spacer comprises a first surface and a second surface that are positioned along the first direction, and
wherein the gate insulating film covers the first surface and the gate electrode covers the second surface.

14. The semiconductor device of claim 12, further comprising a source/drain pattern that is connected to at least one of the plurality of channel layers in the second direction,
wherein the spacer is connected to the source/drain pattern.

15. The semiconductor device of claim 1, further comprising a source/drain pattern that is connected to at least one of the plurality of channel layers in the second direction,
wherein the source/drain pattern comprises an upper surface that is coplanar with an upper surface of the gate electrode.

16. The semiconductor device of claim 15, wherein the source/drain pattern comprises a lower surface that is coplanar with a lower surface of the gate electrode.

17. The semiconductor device of claim 1, wherein the width of each respective channel layer in the first direction is between 0.3 nanometers and 0.5 nanometers, and wherein the plurality of channel layers are spaced apart in both the first and second directions.

18. A semiconductor device comprising:
a gate electrode extending lengthwise in a first direction;
a plurality of channel layers that penetrate the gate electrode in a second direction intersecting the first direction, are spaced apart in the first direction, and comprise a 2D material between 0.1 nanometers and 10 nanometers thick;
a gate insulating film including a plurality of gate insulating film patterns, each gate insulating film pattern at least partially covering a respective channel layer of the plurality of channel layers;
a source/drain pattern that is connected to at least one of the plurality of channel layers in the second direction;
a frontside interlayer insulating film that covers an upper surface of the gate electrode and an upper surface of the source/drain pattern in a third direction intersecting the first direction and the second direction;
a backside interlayer insulating film that covers a lower surface of the gate electrode and a lower surface of the source/drain pattern in the third direction;
a frontside gate contact that penetrates the frontside interlayer insulating film to be connected with the gate electrode; and
a backside gate contact that penetrates the backside interlayer insulating film to be connected with the gate electrode,
wherein a height of each respective channel layer of the plurality of channel layers in the third direction is greater than a width of the respective channel layer in the first direction.

19. The semiconductor device of claim 18, wherein each of the plurality of channel layers comprises a multilayer film.

20. The semiconductor device of claim 18, wherein a thickness of each of the plurality of channel layers in the first direction is smaller than a thickness of the gate insulating film in the first direction.

21. A semiconductor device comprising:
a gate electrode extending lengthwise in a first direction;
a plurality of channel layers that penetrate the gate electrode in a second direction intersecting the first direction, are spaced apart in the first direction, and comprise a 2D material between 0.1 nanometers and 10 nanometers thick;
a gate insulating film including a plurality of gate insulating film patterns, each gate insulating film pattern at least partially surrounding a respective channel layer of the plurality of channel layers; and
a source/drain pattern connected to at least one of the plurality of channel layers in the second direction,
wherein the gate insulating film covers upper surfaces and lower surfaces of the plurality of channel layers that are positioned along a third direction intersecting the first direction and the second direction,
wherein a height of each respective channel layer of the plurality of channel layers in the third direction is greater than a width of the respective channel layer in the first direction,
wherein the source/drain pattern comprises an upper surface that is coplanar with an upper surface of the gate electrode, and
wherein the source/drain pattern comprises a lower surface that is coplanar with a lower surface of the gate electrode.
